(19) United States
(12) Patent Application Publication
(10) Pub. No.: US 2005/0253915 A1
(43) Pub. Date: Nov. 17, 2005

(54) Droplet-discharging apparatus, electrooptic device, electronic apparatus, and method for electrooptic device

(76) Inventors: Ryoichi Matsumoto, Nagano (JP); Takashi Okusa, Nagano (JP); Kenji Kojima, Nagano (JP)

Correspondence Address: HARNESS, DICKEY & PIERCE, P.L.C., P.O. BOX 828, BLOOMFIELD HILLS, MI, 48303, US

(21) Appl. No.: 11/122,310

(22) Filed: May 4, 2005

(30) Foreign Application Priority Data
May 14, 2004 (JP) 2004-144866

(51) Int. Cl. B41J 2/01

(52) U.S. Cl. 347/104

(57) ABSTRACT

A droplet-discharging apparatus for discharging a droplet onto a base through the nozzle of a head, the apparatus including: a platform retaining the base; a plurality of transportation units, each including a head group having at least one head with a nozzle line and each being moved in the sub-scanning direction on an axis or on a plurality of axes disposed parallel to each other; and a position-controlling unit for adjusting relative position of the adjacent head groups arranged in the main scanning direction or in the sub-scanning direction to adjust the nozzle pitch by independently driving the plurality of transportation units, wherein the droplet is discharged onto predetermined portions on the base from the head group while the transportation units are relatively moved for the platform in the main scanning direction.

### BACKGROUND OF THE INVENTION

1. Technical Field

The present invention relates to an electrooptic device, an electronic apparatus, and a droplet-discharging apparatus. In particular, the invention relates to an electrooptic device, an electronic apparatus, and a droplet-discharging apparatus for suitably applying a liquid material to periodically arranged regions in, for example, a color-filter substrate or a color-matrix display.

2. Related Art

Thin films have been generally formed by, for example, spin coating, which is one type of process for applying a liquid material onto a substrate to form a thin film. In this spin coating, a liquid material is dropped onto a substrate, and then the substrate is rotated to spread the liquid material across the surface of the substrate, thus forming a thin film. The film thickness is controlled by, for example, the number of rotations, the time of rotation, and the viscosity of the liquid material used.

However, in the spin coating, most of the liquid material supplied is splattered; hence, an excessive liquid material is required. This is wasteful and drives the production costs up. Furthermore, the liquid material is moved from an inner portion to an outer portion by centrifugal force caused by the rotation of the substrate. As a result, the film thickness at the outer portion tends to be higher than that at the inner portion and is thus nonuniform.

According to such circumstances, droplet-discharging processes, such as an inkjet process, and inkjet apparatuses used in the processes have recently been proposed. Each of the inkjet apparatuses can deliver a predetermined liquid material to a desired position. Thus, the inkjet apparatuses have been suitably used for mainly forming a thin film. For example, Japanese Unexamined Patent Application Publication No. 2003-127343 discloses filter elements in a color filter substrate and luminescent portions arrayed in a matrix in a matrix display formed with an inkjet apparatus.

According to trends towards a higher pixel density in a color display etc., with respect to a filter element or the like in a color filter substrate, a plurality of predetermined portions to be applied with a material by discharging need to be densely arranged. The term “predetermined portions to be applied with a material by discharging” refers to portions where, for example, filter elements will be formed. Therefore, there have been demands for a high-density inkjet head used in such an inkjet apparatus. If an inkjet head having the same width as that of a base can be produced, the predetermined portions on the base can be applied with a material with high accuracy in a single operation. However, it is very difficult to produce nozzles in such an inkjet head with high accuracy. The number of nozzles that can be produced in-one inkjet head with high accuracy is at most about 200 to 400. Accordingly, a process has been employed for increasing the width, in which the apparatus can discharge a material in a single operation, using a carriage including a plurality of inkjet heads disposed along with the carriage. In this case, the plurality of inkjet heads are positioned on the carriage and then are assembled. When a desired nozzle pitch is not achieved because of low fabrication accuracy, it is necessary to disassemble and then assemble again. That is, there is a problem with difficulty in adjusting the nozzle pitch.

### SUMMARY

An advantage of the invention is a droplet-discharging apparatus in which a nozzle pitch is easily adjustable, the droplet-discharging apparatus being capable of discharging with high accuracy. An another advantage of the invention is an electro-optical device produced with the droplet-discharging apparatus, a method for producing the electro-optical device with the droplet-discharging apparatus, and a electronic apparatus including the electro-optical device produced with the droplet-discharging apparatus.

According to a first aspect of the invention, a droplet-discharging apparatus for discharging a droplet onto a base through the nozzle of a head, the apparatus including a platform retaining the base; a plurality of transportation units, each including a head group having at least one head with a nozzle line and each being moved in the sub-scanning direction on an axis or on a plurality of axes disposed parallel to each other; and a position-controlling unit for adjusting relative position of the adjacent head groups arranged in the main scanning direction or in the sub-scanning direction to adjust the nozzle pitch by independently driving the plurality of transportation units, wherein the droplet is discharged onto predetermined portions on the base from the head group while the transportation units are relatively moved for the platform in the main scanning direction.

Accordingly, in the droplet-discharging apparatus, a nozzle pitch between heads provided on a plurality of transportation units can be adjusted by a simple method. As a result, discharging can be performed with high accuracy.

In this case, the position-controlling unit synchronously may move the plurality of transportation units in the sub-scanning direction while the adjusted relative position is maintained. As a result, discharging onto the entire surface of the base can be performed at the adjusted nozzle pitch.

In this case, the position-controlling unit may adjust the relative position of the head groups on the adjacent transportation units arranged along the sub-scanning direction or the main scanning direction so that the nozzle pitch along the sub-scanning direction is uniformly spaced. As a result, discharging onto the base can be performed at an increased scan width. Thus, the number of scanning can be reduced.

In this case, the position-controlling unit may adjust the relative position of the head groups on the adjacent transportation units arranged along the sub-scanning direction or the main scanning direction so that the linear density of the nozzles along the sub-scanning direction is increased. As a result, high-density discharging can be performed at a desired nozzle pitch.

In this case, the planar image of the predetermined portions may have a nearly rectangular shape having a long side and a short side; and the platform may retain the base so that the long side of each predetermined portion is parallel to the sub-scanning direction and the short side of each predetermined portion is parallel to the main scanning direction. As a result, the droplets can be discharged onto the predetermined portions having a rectangular shape.

In this case, the nozzle line in the head constituting the head group may be disposed parallel to the sub-scanning direction. As a result, the droplets can be discharged at an increased scan width with high accuracy.

In this case, the nozzle line in the head constituting the head group may be disposed at an angle to the sub-scanning direction. As a result, the droplets can be discharged with high accuracy.

In this case, an electro-optical device may be produced with the droplet-discharging apparatus. As a result, the electro-optical device can be produced with high accuracy.

In this case, a method for producing an electro-optical device with the droplet-discharging apparatus may be performed. As a result, an electro-optical device capable of displaying high-definition images can be provided.

In this case, an electronic apparatus may include the electro-optical device. As a result, an electronic apparatus including an electro-optical device capable of displaying high-definition images can be provided.

### BRIEF DESCRIPTION OF THE DRAWINGS

The invention will be described with reference to the accompanying drawings, wherein like numbers reference like elements, and wherein:

FIG. 1 is a schematic view showing a droplet-discharging apparatus according to an embodiment;

FIG. 2 is a schematic view showing a first carriage and a second carriage according to an embodiment;

FIG. 3 is a schematic view showing a head according to an embodiment;

FIG. 4A is a partially schematic view showing a discharging head of the head according to an embodiment;

FIG. 4B is a sectional partially schematic view showing the discharging head of the head according to an embodiment;

FIG. 5 is a schematic view showing relative positions of heads in each head group according to an embodiment;

FIG. 6 is a schematic view showing a controlling unit according to an embodiment;

FIG. 7A is a schematic view showing a head-driving unit according to an embodiment;

FIG. 7B is a timing chart showing a driving signal, selection signals, and discharging signals at the head-driving unit according to an embodiment;

FIG. 8 is a schematic view illustrating a method for applying a material with the droplet-discharging apparatus according to an embodiment;

FIG. 9A is a schematic view showing a relative position of the first and second carriages according to a modified embodiment;

FIG. 9B is a schematic view showing an arrangement of heads according to a modified embodiment;

FIGS. 10A and 10B each are a schematic view showing carriages according to Modification 1;

FIG. 11 is a schematic view showing carriages according to Modification 2;

FIG. 12 is a flow chart illustrating steps of producing a color filter;

FIGS. 13A to 13E each are a schematic cross-sectional view of a color filter;

FIG. 14 is a sectional partially schematic view showing a liquid crystal display device with the color filter according to an embodiment;

FIG. 15 is a sectional partially schematic view showing a second example of a liquid crystal display device with the color filter according to an embodiment;

FIG. 16 is an exploded perspective view showing a third example of a liquid crystal display device with the color filter according to an embodiment;

FIG. 17 is a partially cross-sectional view showing an organic electroluminescent display;

FIG. 18 is a flow chart illustrating steps of producing an organic electroluminescent display;

FIG. 19 is a cross-sectional view illustrating a step of forming inorganic bank layers;

FIG. 20 is a cross-sectional view illustrating a step of forming organic bank layers;

FIG. 21 is a cross-sectional view illustrating a step of forming a hole injecting and/or transporting layer;

FIG. 22 is a cross-sectional view showing the hole injecting and/or transporting layers;

FIG. 23 is a cross-sectional view illustrating a step of forming a luminescent layer emitting blue light;

FIG. 24 is a cross-sectional view showing the luminescent layer emitting blue light;

FIG. 25 is a cross-sectional view showing luminescent layers emitting red, green, and blue light;

FIG. 26 is a cross-sectional view illustrating a step of forming-an anode;

FIG. 27 is a exploded partially perspective view showing a plasma display panel (PDP);

FIG. 28 is a partially cross-sectional view showing a field emission display (FED);

FIG. 29A is a perspective view showing a personal computer with an electro-optical device according to an embodiment; and

FIG. 29B is a perspective view showing a cellular telephone according to an embodiment.

### DESCRIPTION OF THE EMBODIMENTS

The invention will be described in detail below with reference to the drawings. The invention is not limited to the embodiments. The embodiments described below include a constituent easily conceived by those skilled in the art easily conceive or a substantially identical constituent.

Preferred embodiments of a droplet-discharging apparatus, an electro-optical device, an electronic apparatus, and a method for producing the electro-optical device according to the invention will be described in detail in order of the following headings: [Droplet-Discharging Apparatus], [Production of Electro-optical Device], and [Application to Electronic Apparatus].

[Droplet-Discharging Apparatus]

A droplet-discharging apparatus according to an embodiment of the invention will be described in detail in order of the following headings: (Entire Configuration of Droplet-Discharging Apparatus), (Carriage), (Head), (Head Group), (Controlling Unit), (Method for Applying Material), (Modification of Relative Position), (Modification of Head Arrangement), (Modification 1 of Carriage), and (Modification 2 of Carriage).

(Entire Configuration of Droplet-Discharging Apparatus)

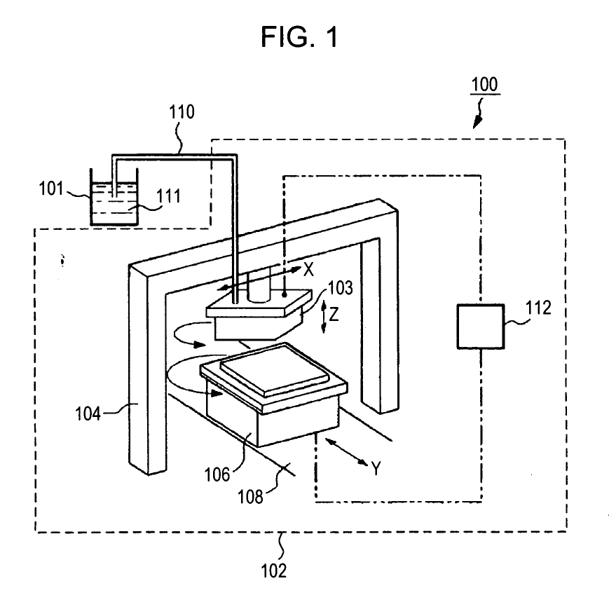

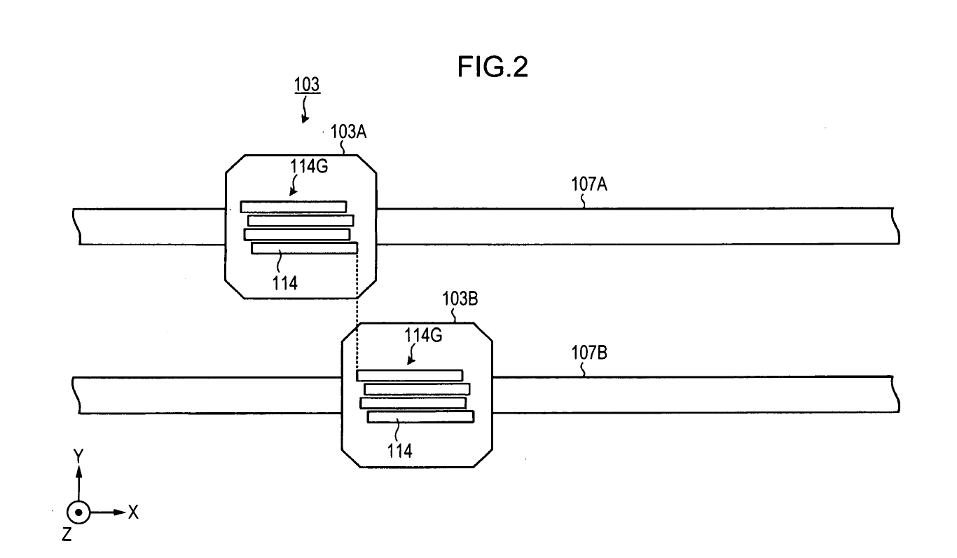

FIG. 1 is a schematic view showing the entire configuration of a droplet-discharging apparatus 100. The droplet-discharging apparatus 100 includes a tank 101 containing a liquid material 111, a tube 110, and a discharging and scanning section 102, the liquid material 111 being supplied from the tank 101 to the discharging and scanning section 102 through the tube 110. The discharging and scanning section 102 includes a carriage group (transportation unit) 103 having a plurality of heads 114 (see FIG. 2), a first position-controlling unit 104 for controlling the position of the carriage group 103, a platform 106 for holding a base described below, a second position-controlling unit 108 for controlling the position of the platform 106, and a controlling unit 112. The tank 101 is connected to the plurality of heads 114 via the tube 110. The liquid material 111 is supplied from the tank 101 to each of the heads 114.

The first position-controlling unit 104 transports the carriage group 103 along the x-axis (sub-scanning direction) and the z-axis perpendicular to the z-axis according to a signal sent from the controlling unit 112. Furthermore, the first position-controlling unit 104 also can rotate the carriage group 103 around an axis parallel to the z-axis. In this embodiment, the z-axis is defined as a direction parallel to a vertical direction (the direction of the acceleration of gravity). The second position-controlling unit 108 transports the platform 106 along the y-axis (main scanning direction) perpendicular to both of the x-axis and z-axis according to a signal sent from the controlling unit 112. Furthermore, the second position-controlling unit 108 also can rotate the platform 106 around an axis parallel to the z-axis. In this specification, each of the first position-controlling unit 104 and the second position-controlling unit 108 is sometimes referred to as a “scanning section”.

The platform 106 has a plane parallel to both of the x-axis and y-axis. Furthermore, the platform 106 can fix or hold a base on the plane, the base including predetermined portions to be applied with a predetermined material by discharging. In this specification, the base including the predetermined portions is sometimes referred to as a “receiving substrate”.

In this specification, the directions of the x-axis, y-axis, and z-axis are identical to the respective directions in which the carriage group 103 and the platform 106 are relatively moved. The virtual origin point of the x-y-z coordinate system defining the x-axis, y-axis, and z-axis is fixed at a reference point of the droplet-discharging apparatus 100. The term “x coordinate”, “y coordinate”, and “z coordinate” in this specification means coordinates in the x-y-z coordinate system. The virtual origin point may be fixed at the platform 106 or at the carriage group 103.

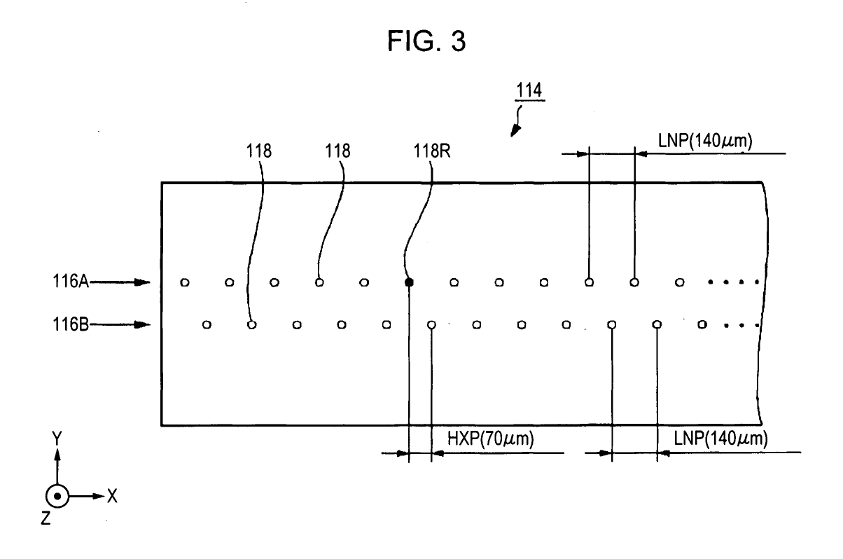

As described above, the carriage group 103 is moved along the x-axis by the first position-controlling unit 104. On the other hand, the platform 106 is moved along the y-axis by the second position-controlling unit 108. That is, the relative position of each of the heads 114 is changed with reference to the platform 106 by the first and second position-controlling units 104 and 108. In particular, the carriage group 103, head groups 114G (see FIG. 2), the heads 114, or nozzles 118 (see FIG. 3) is maintained at a predetermined distance with respect to the z-axis from the predetermined portions on a base fixed on the platform 106 and is relatively moved along the x-axis or y-axis, i.e., is relatively scanned. Here, the carriage group 103 may be moved along the y-axis for the predetermined portions remaining at rest. The liquid material 111 may be discharged toward the portions remaining at rest through the nozzles 118 while the carriage group 103 is moving along the y-axis between two predetermined points. The term “relative moving” or “relative scanning” means that at least either a component for discharging the liquid material 111 or a component for receiving the material is moved relative to another.

Relative movement of the carriage group 103, head groups 114G (see FIG. 2), the heads 114, or nozzles 118 (see FIG. 3) results in a change in the relative position of these with reference to the platform, the base, or the predetermined portions. Thus, in this specification, it is expressed that the carriage group 103, head groups 114G, the heads 114, or nozzles 118 is relatively moved with reference to the platform 106, the base, or the predetermined portions even when the platform 106 is moved alone while the carriage group 103, head groups 114G, the heads 114, or nozzles 118 is remaining at rest. The combination of “relative scanning” or “relative moving” and “discharging a material” is sometimes referred to as “applying scan”.

The carriage group 103 and the platform 106 further have the degree of freedom in translation and rotation other than the movements described above. However, in this embodiment, the description about the degree of freedom in translation and rotation other than the movements described above is omitted in order to facilitate the description.

The controlling unit 112 receives discharge data including the data of relative positions where the liquid material 111 is discharged from an external information processor. The configuration and functions of the controlling unit 112 will be described below.

(Carriage)

FIG. 2 is a schematic view showing the carriage group 103 observed from the platform 106. A direction perpendicular to the plane of the paper on which FIG. 2 is drawn is defined as the z-axis direction. The horizontal direction of the FIG. 2 is defined as the x-axis direction (sub-scanning direction) and the vertical direction of the FIG. 2 is defined as the y-axis direction (main scanning direction).

As shown in FIG. 2, the carriage group (transportation unit) 103 includes a first carriage (transportation unit) 103A and a second carriage (transportation unit) 103B, both of the first carriage 103A and the second carriage 103B being disposed on the same xy-plane. The first carriage 103A is moved on a first feed shaft 107A along the x-axis under the control of the first position-controlling unit 104. The second carriage 103B is moved on a second feed shaft 107B along the x-axis under the control of the first position-controlling unit 104, the first and second feed shafts 107A and 107B being parallel to each other and being on the same xy-plane. In this way, the first and second feed shafts 107A and 107B can be independently moved along the x-axis direction.

The first and second carriages 103A and 103B each include a head group 114G. Each head group 114G includes four heads 114. The arrangement of the heads 114 in either the first carriage or the second carriage is identical to that of the heads 114 in another carriage. Each of the heads 114 have the undersurface provided with a plurality of nozzles 118. The undersurface of each head 114 is in the form of a polygon having two long sides and two short sides. As shown in FIG. 2, the undersurfaces of the heads 114 on the respective first and second carriages 103A and 103B face toward the platform 106. The long side and the short side are parallel to the x-axis and y-axis, respectively. The relative positions of the heads 114 will be described in detail below.

The first carriage 103A and the second carriage 103B are relatively moved so as to have a predetermined nozzle pitch between the head group 114G on the first carriage 103A and the head group 114G on the second carriage 103B by the first position-controlling unit 104. FIG. 2 shows that the head group 114G on the first carriage 103A and the head group 114G on the second carriage 103B are disposed along the x-axis so as to double the width in which the apparatus can discharge a material in a single operation. There are various processes for adjusting the relative position between the first and second carriages 103A and 103B. For example, there are first and second processes described below.

(1) First Process

The first carriage 103A and the second carriage 103B are disposed at predetermined positions. Then, a test pattern is drawn with the liquid material 111 on a base. The amount of displacement between the pattern drawn with the head group 114G on the first carriage 103A and the pattern drawn with the head group 114G on the second carriage 103B is measured. The nozzle pitch is adjusted by relatively moving the first and second carriages 103A and 103B by the resulting amount of displacement.

(2) Second Process

Pins are set at the nozzles of the heads 114 on both of the first and second carriages 103A and 103B. The pins are photographed by a camera, and then the distance between the pins is measured. The difference between the resulting distance and a target distance is calculated. The nozzle pitch is adjusted by relatively moving the first and second carriages 103A and 103B by the resulting difference.

After the adjustment of the relative position, the first and second carriages 103A and 103B are synchronously moved along the x-axis by the first position-controlling unit 104 while the relative position of the first and second carriages 103A and 103B is maintained. However, the first and second carriages 103A and 103B need not to be synchronously moved as long as the relative position can be maintained after the carriages are moved. This can be applied to the following description.

In this embodiment, the head groups 114G each have four heads. However, the number of heads included in one head group 114G is not limited. One head group 114G may have one head alone. In this specification, the term “head group” refers to a group including at least one head.

(Head)

FIG. 3 shows the undersurface of each head 114. Each of the heads 114 includes a plurality of nozzles 118 arranged in two lines along the x-axis. The plurality of nozzles 118 are arranged so that the nozzle pitch HXP of each head 114 along the x-axis is about 70 μm. The term “nozzle pitch HXP of each head 114 along the x-axis” refers to the pitch between the projected nozzle images obtained by projecting all of the nozzles 118 in each head 114 onto the x-axis along the y-axis.

In this embodiment, the plurality of nozzles 118 in each head 114 are arranged in a first nozzle line 116A and a second nozzle line 116B. The first and second nozzle lines 116A and 116B are arranged perpendicular to the y-axis. Each of the first and second nozzle lines 116A and 116B includes 180 nozzles 118 uniformly spaced along the x-axis. This space is about 140 μm. That is, both of the nozzle pitch LNP of the first nozzle line 116A and the nozzle pitch LNP of the second nozzle line 116B are about 140 μm.

The nozzle positions of the second nozzle line 116B are shifted in the positive direction of the x-axis (to the right of FIG. 3) by half the nozzle pitch LNP (about 70 μm) with reference to the nozzle positions of the first nozzle line 116A. Therefore, the nozzle pitch HXP along the x-axis of each head 114 is half the nozzle pitch LNP of the first nozzle line 116A (or second nozzle line 116B) (about 70 μm).

Thus, the linear density of the nozzles in each head 114 along the x-axis is twice that of the first nozzle line 116A (or the second nozzle line 116B). In this specification, the term “linear density of the nozzles along the x-axis” refers to the number of projected nozzle images per unit length, the projected nozzle images being obtained by projecting a plurality of nozzles onto the x-axis along the y-axis.

The number of nozzle lines in each head 114 is not limited to two. Each head 114 may include M nozzle lines, where M represents an integer of 1 or more. In this case, the plurality of nozzles 118 in each of the M nozzle lines are arranged at a nozzle pitch LNP of M times the nozzle pitch HXP. When M represents an integer of 2 or more, with reference to a nozzle line among M nozzle lines, the nozzle positions of each of the other (M-1) nozzle lines are shifted along the x-axis by i times the nozzle pitch HXP without overlaps, where i represents an integer of 1 to (M-1).

Since the first and second nozzle lines 116A and 116B each include 180 nozzles, each head 114 includes 360 nozzles. The 10 nozzles at each end of the first nozzle line 116A are defined as “nonoperating nozzles”. The 10 nozzles at each end of the second nozzle line 116B are also defined as “nonoperating nozzles”. The liquid material 111 is not discharged through the 40 nonoperating nozzles. That is, the liquid material 111 is discharged through the 320 nozzles 118 among the 360 nozzles 118 in each head 114. In this specification, the 320 nozzles 118 is sometimes referred to as “discharging nozzles”.

In this specification, in order to describe the relative position of the heads 114, among the 180 nozzles 118 in the first nozzle line 116A, the eleventh nozzle 118 from the left extremity is defined as “reference nozzle 118R”. That is, among the 160 discharging nozzles in the first nozzle line 116A, one discharging nozzle at the left extremity is defined as the “reference nozzle 118R” of each head 114. The “reference nozzle 118R” need not be set at the above-described position as long as the same definition of the reference nozzle 118R is used for all heads 114.

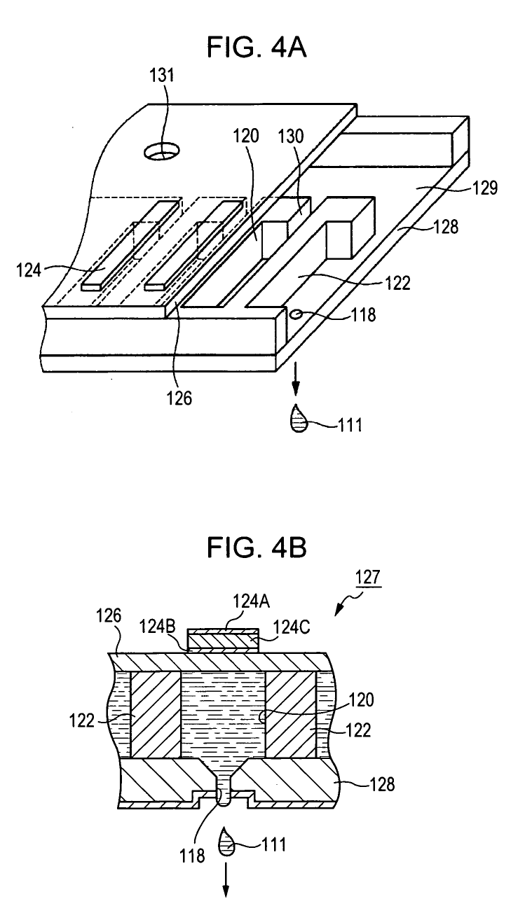

As shown in FIGS. 4A and 4B, the heads 114 is inkjet heads. In particular, each of the heads 114 includes a diaphragm 126 and a nozzle plate 128. A liquid reservoir 129 is provided between the diaphragm 126 and the nozzle plate 128, the liquid reservoir 129 being always filled with the liquid material 111 fed from the tank 101 through a hole 131.

A plurality of partitions 122 are provided between the diaphragm 126 and the nozzle plate 128. A space surrounded by the diaphragm 126, the nozzle plate 128, and a pair of partitions 122 is defined as a cavity 120. Since the cavities 120 are provided corresponding to the nozzles 118, the number of cavities 120 is equal to the number of nozzles 118. The liquid material 111 is fed from the liquid reservoirs 129 to the cavities 120 through a feeding aperture 130 between a pair of partitions 122.

Vibrators 124 are provided on the diaphragm 126 corresponding to the respective cavities 120. Each of the vibrators 124 includes a pair of electrodes 124A and 124B and a piezoelectric element 124C between the electrodes. A driving voltage is applied between a pair of electrodes 124A and 124B to discharge the liquid material 111 from the corresponding nozzle 118. The shape of each nozzle 118 is adjusted so that the liquid material is discharged along the z-axis from each nozzle 118.

In this specification, the term “liquid material” refers to a material having a viscosity such that the material can be discharged through the nozzle. In this case, the material may be hydrophilic or lipophilic. There is no problem as long as the material has a fluidity (viscosity) such that the material can be discharged through the nozzle. The material may contain a solid component as long as the material can flow in its entirety.

The controlling unit 112 (see FIG. 1) may independently send a signal to each of the plurality of vibrators 124. That is, the volumes of liquid material 111 discharged through the respective nozzles 118 may be each controlled according to the signal sent from the controlling unit 112. In such a case, the volume of liquid material 111 discharged through each nozzle 118 can be changed between 0 to 42 pL. In addition, the controlling unit 112 can set a discharging nozzle 118 and a non-discharging nozzle 118 during the applying scan as described below.

In this specification, a portion including the nozzle 118, the cavity 120 corresponding to the nozzle 118, and the vibrator 124 corresponding to the cavity 120 is sometimes referred to as “discharging portion 127”. One head 114 has the same number of discharging portions 127 as the number of nozzles 118. Each discharging portion 127 may include an electrothermal transducer instead of the piezoelectric element. That is, in the discharging portion 127, a material may be discharged by causing thermal expansion of a material with the electrothermal transducer.

(Head Group)

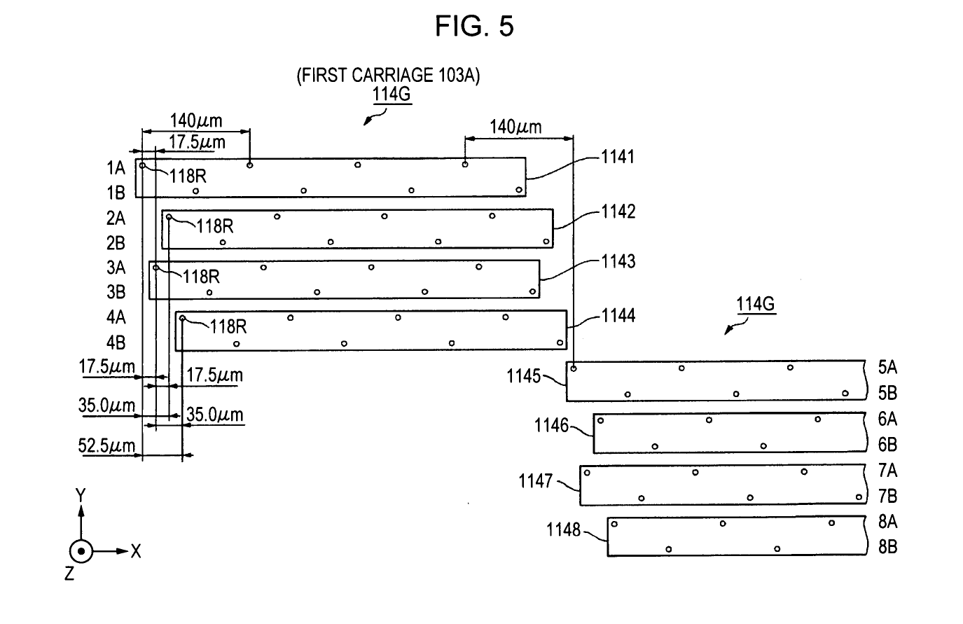

The relative positions of four heads 114 in each head group 114G will be described below. With respect to the carriage group 103 including the first and second carriages 103A and 103B shown in FIG. 2, FIG. 5 shows adjacent two head groups 114G arranged along the y-axis.

As shown in FIG. 5, each of the head group 114G includes four heads 114. The four heads 114 in each head group 114G are arranged so that the nozzle pitch GXP along the x-axis of the head group 114G is a quarter of the nozzle pitch HXP of the head group 114G along the x-axis. With reference to the x coordinate of a reference nozzle 118R in a head 114, the x coordinates of the reference nozzles 118R in the other heads 114 are shifted by j/4 times the nozzle pitch HXP without overlaps, where j is an integer of 1 to 3. Thus, the nozzle pitch GXP of each head group 114G along the x-axis is a quarter of the nozzle pitch HXP.

In this embodiment, since the nozzle pitch HXP of each head 114 along the x-axis is about 70 μm, the nozzle pitch GXP of the head group 114G along the x-axis is a quarter of the nozzle pitch HXP, i.e., the nozzle pitch GXP is about 17.5 μm. The term “nozzle pitch GXP of each head group 114G along the x-axis” refers to the pitch between the projected nozzle images obtained by projecting all of the nozzles 118 in each head group 114G onto the x-axis along the y-axis.

The number of heads 114 in each head group 114G is not limited to four. Each head group 114G may include N heads 114, where N represents an integer of 2 or more. In this case, the N heads 114 in each head group 114G need to be arranged so that the nozzle pitch GXP is 1/N times the nozzle pitch HXP. Alternatively, with reference to the x coordinate of a reference nozzle 118R in a head 114 among N heads 114, the x coordinates of the reference nozzles 118R in the other (N-1) heads 114 should be shifted by j/N times the nozzle pitch HXP without overlaps, where j represents an integer of 1 to (N-1).

The relative positions of the heads 114 according to this embodiment will be described in detail below.

To facilitate the description, the four heads 114 in the head group 114G at the upper left in FIG. 5 are defined as a head 1141, a head 1142, a head 1143, and a head 1144, in order from the top. The four heads 114 in the head group 114G at the lower right in FIG. 5 are defined as a head 1145, a head 1146, a head 1147, and a head 1148, in order from the top.

The first and second nozzle lines 116A and 116B in the head 1141 is defined as nozzle lines 1A and 1B, respectively. The first and second nozzle lines 116A and 116B in the head 1142 is defined as nozzle lines 2A and 2B, respectively. The first and second nozzle lines 116A and 116B in the head 1143 is defined as nozzle lines 3A and 3B, respectively. The first and second nozzle lines 116A and 116B in the head 1144 is defined as nozzle lines 4A and 4B, respectively. The first and second nozzle lines 116A and 116B in the head 1145 is defined as nozzle lines 5A and 5B, respectively. The first and second nozzle lines 116A and 116B in the head 1146 is defined as nozzle lines 6A and 6B, respectively. The first and second nozzle lines 116A and 116B in the head 1147 is defined as nozzle lines 7A and 7B, respectively. The first and second nozzle lines 116A and 116B in the head 1148 is defined as nozzle lines 8A and 8B, respectively.

In fact, each of the nozzle lines 1A to 8B includes 180 nozzles 118. As described above, the 180 nozzles 118 are aligned along the x-axis in each of the nozzle lines 1A to 8B. In FIG. 5, for convenience in describing, each of the nozzle lines 1A to 8B includes four discharging nozzles (nozzles 118). Furthermore, the leftmost nozzle 118 in the nozzle line 1A is defined as a reference nozzle 118R of the head 1141. The leftmost nozzle 118 in the nozzle line 2A is defined as a reference nozzle 118R of the head 1142. The leftmost nozzle 118 in the nozzle line 3A is defined as a reference nozzle 118R of the head 1143. The leftmost nozzle 118 in the nozzle line 4A is defined as a reference nozzle 118R of the head 1144. The leftmost nozzle 118 in the nozzle line 5A is defined as a reference nozzle 118R of the head 1145.

The absolute value of the difference between the x coordinate of the reference nozzle 118R of the head 1141 and the x coordinate of the reference nozzle 118R of the head 1142 is a quarter of the nozzle pitch LNP, i.e., the absolute value is half of the nozzle pitch HXP. In FIG. 5, the position of the reference nozzle 118R of the head 1141 is shifted by a quarter of the nozzle pitch LNP in the negative direction (leftward in FIG. 5) along the x-axis with reference to the position of the reference nozzle 118R of the head 1142. The head 1141 may be shifted in the positive direction (rightward in FIG. 5) along the x-axis based on the head 1142.

The absolute value of the difference between the x coordinate of the reference nozzle 118R of the head 1143 and the x coordinate of the reference nozzle 118R of the head 1144 is a quarter of the nozzle pitch LNP, i.e., the absolute value is half of the nozzle pitch HXP. In FIG. 5, the position of the reference nozzle 118R of the head 1143 is shifted by a quarter of the nozzle pitch LNP in the negative direction (leftward in FIG. 5) along the x-axis with reference to the position of the reference nozzle 118R of the head 1144. The head 1143 may be shifted in the positive direction (rightward in FIG. 5) along the x-axis based on the head 1144.

The absolute value of the difference between the x coordinate of the reference nozzle 118R of the head 1142 and the x coordinate of the reference nozzle 118R of the head 1143 is ⅛ or ⅜ times the nozzle pitch LNP, i.e., the absolute value is ¼ or ¾ times the nozzle pitch HXP. In FIG. 5, the position of the reference nozzle 118R of the head 1142 is shifted by ⅛ times the nozzle pitch LNP, i.e., the position is shifted by 17.5 μm in the positive direction (rightward in FIG. 5) along the x-axis with reference to the position of the reference nozzle 118R of the head 1143. The head 1142 may be shifted in the negative direction (leftward in FIG. 5) along the x-axis based on the head 1143.

In this embodiment, the heads 1141, 1142, 1143, and 1144 are arranged in that order in the negative direction along the y-axis. The arrangement of the four heads 114 along the y-axis may be changed. That is, the arrangement may be changed as long as the head 1141 is adjacent to the head 1142 along the y-axis and the head 1143 is adjacent to the head 1144.

According to the above-described arrangement, the x coordinate of the leftmost nozzle 118 in the nozzle line 2A, the x coordinate of the leftmost nozzle 118 in the nozzle line 3A, and the x coordinate of the leftmost nozzle 118 in the nozzle line 4A are provided between the x coordinate of the leftmost nozzle 118 in the nozzle line 1A and the x coordinate of the leftmost nozzle 118 in the nozzle line 1B. The x coordinate of the leftmost nozzle 118 in the nozzle line 2B, the x coordinate of the leftmost nozzle 118 in the nozzle line 3B, and the x coordinate of the leftmost nozzle 118 in the nozzle line 4B are provided between the x coordinate of the leftmost nozzle 118 in the nozzle line 1B and the x coordinate of the second nozzle 118 from the left extremity. The x coordinate of the leftmost nozzle 118 in the nozzle line 2A (or 2B), the x coordinate of the leftmost nozzle 118 in the nozzle line 3A (or 3B), and x coordinate of the leftmost nozzle 118 in the nozzle line 4A (or 4B) are provided between the x coordinate of each of the other nozzles 118 in the nozzle line 1A and the x coordinate of each of the other nozzles 118 in the nozzle line 1B.

More specifically, according to the head arrangement, the x coordinate of the leftmost nozzle 118 in the nozzle line 1B substantially corresponds with the x coordinate of the middle between the x coordinate of the leftmost nozzle 118 in the nozzle line 1A and the x coordinate of the second nozzle 118 in the nozzle line 1A. The x coordinate of the leftmost nozzle 118 in the nozzle line 2A substantially corresponds with the x coordinate of the middle between the x coordinate of the leftmost nozzle 118 in the nozzle line 1A and the x coordinate of the leftmost nozzle 118 in the nozzle line 1B. The x coordinate of the leftmost nozzle 118 in the nozzle line 2B substantially corresponds with the x coordinate of the middle between the x coordinate of the second nozzle 118 from the left extremity and the x coordinate of the leftmost nozzle 118 in the nozzle line 1B. The x coordinate of the leftmost nozzle 118 in the nozzle line 3A substantially corresponds with the x coordinate of the middle between the x coordinate of the leftmost nozzle 118 in the nozzle line 1A and the x coordinate of the leftmost nozzle 118 in the nozzle line 2A. The x coordinate of the leftmost nozzle 118 in the nozzle line 3B substantially corresponds with the x coordinate of the middle between the x coordinate of the leftmost nozzle 118 in the nozzle line 1B and the x coordinate of the leftmost nozzle 118 in the nozzle line 2B. The x coordinate of the leftmost nozzle 118 in the nozzle line 4A substantially corresponds with the x coordinate of the middle between the x coordinate of the leftmost nozzle 118 in the nozzle line 1B and the x coordinate of the leftmost nozzle 118 in the nozzle line 2A. The x coordinate of the leftmost nozzle 118 in the nozzle line 4B substantially corresponds with the x coordinate of the middle between the x coordinate of the second nozzle 118 from the left extremity in the nozzle line 1A and the x coordinate of the leftmost nozzle 118 in the nozzle line 2B.

The arrangement of the heads 1145, 1146, 1147, and 1148 in the head group 114G at lower right in FIG. 5 is identical to that of the heads 1141, 1142, 1143, and 1144.

Next, the relative position of the first and second carriages 103A and 103B is adjusted so that the adjacent two head groups 114G along the x-axis are arranged at the following relative position. The relative position of the adjacent two head groups 114G along the x-axis will be described based on the relative position of the heads 1141 and 1145 below.

The position of the reference nozzle 118R in the head 1145 is shifted by the product of the nozzle pitch HXP of each head 114 along the x-axis and the number of discharging nozzles in the head 114 in the positive direction along the x-axis from the position of the reference nozzle 118R in the head 1141. In this embodiment, since the nozzle pitch HXP is about 70 μm and the number of discharging nozzles in each head 114 is 320, the position of the reference nozzle 118R in the head 1145 is shifted by 22.4 mm (70 μm×320) from the position of the reference nozzle 118R in the head 1141 in the positive direction along the x-axis. In FIG. 5, for convenience in describing, the number of discharging nozzles in the head 1141 is 8. Thus, the position of the reference nozzle 118R in the head 1145 is shifted by 560 μm (70 μm×8) from the reference nozzle 118R in the head 1141.

Since the heads 1141 and 1145 are arranged as described above, the x coordinate of the rightmost discharging nozzle in the nozzle line 1A is shifted by the nozzle pitch LNP from the x coordinate of the leftmost discharging nozzle in the nozzle line 5A. Therefore, the nozzle pitch of the whole two head groups 114G is a quarter of the nozzle pitch HXP of the head 114 along the x-axis.

The six head groups 114G are arranged so that the nozzle pitch of the whole carriage group 103 along the x-axis is 17.5 μm, i.e., the nozzle pitch is a quarter of the nozzle pitch HXP of the head 114.

(Controlling Unit)

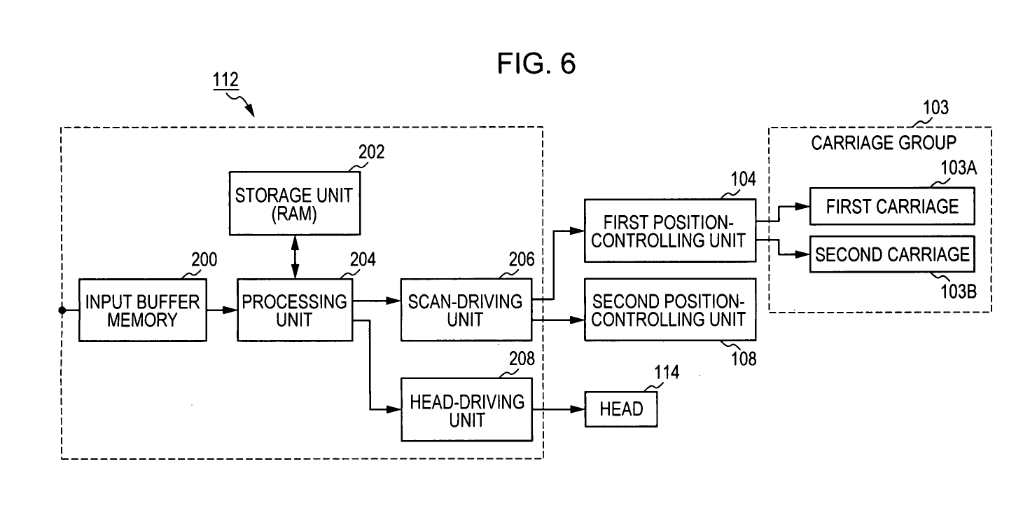

The controlling unit 112 will be described below. As shown in FIG. 6, the controlling unit 112 includes an input buffer memory 200, a storage unit 202, a processing unit 204, a scan-driving unit 206, and a head-driving unit 208. The input buffer memory 200 and the processing unit 204 are communicably connected to each other. The processing unit 204 and the storage unit 202 are communicably connected to each other. The processing unit 204 and the scan-driving unit 206 are communicably connected to each other. The processing unit 204 and the head-driving unit 208 are communicably connected to each other. Furthermore, the scan-driving unit 206 and the first position-controlling unit 104 or the second position-controlling unit 108 are communicably connected to each other. The head-driving unit 208 and the plurality of heads 114 are communicably connected to each other.

The input buffer memory 200 receives discharging data sets for discharging the liquid material 111 from an external information processor. The discharging data sets includes data indicating the relative positions of all of the predetermined portions on a base; data indicating the number of relative scan required for applying the liquid material 111 onto all the predetermined portions so that the predetermined portions filled with the material have desired thicknesses; data specifying the nozzle 118 functioning as an on-nozzle 118A; and data specifying the nozzle 118 functioning as an off-nozzle 118B. The on-nozzle 118A and the off-nozzle 118B will be described below. The input buffer memory 200 supplies the discharging data to the processing unit 204. The discharging data is stored in the storage unit 202 by the processing unit 204. In FIG. 6, the storage unit 202 represents a random-access memory (RAM).

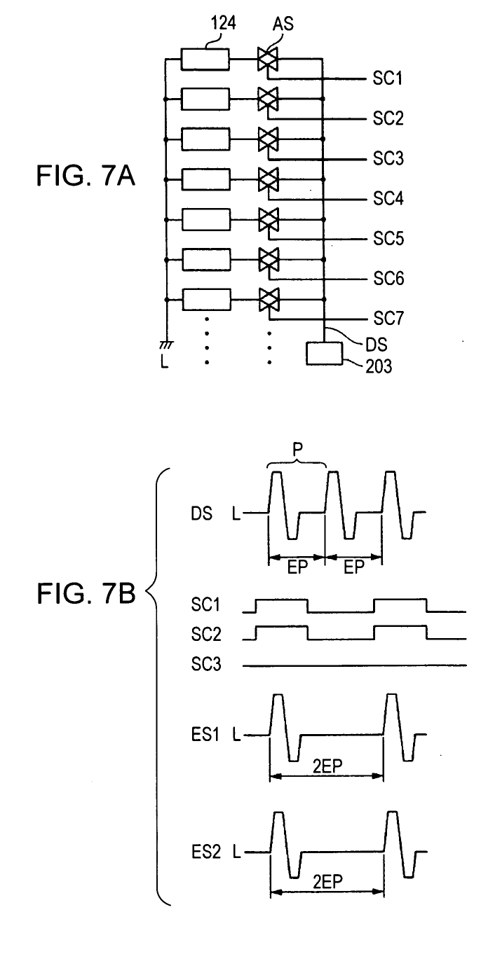

The processing unit 204 provides the scan-driving unit 206 with data indicating the relative positions of the nozzles 118 for the predetermined portions, based on the discharging data in the storage unit 202. The scan-driving unit 206 provides the first position-controlling unit 104 and the second position-controlling unit 108 with a driving signal corresponding to this data and ejection period (EP) (see FIG. 7) described below. As a result, the head 114 is relatively scanned for the predetermined portions. The processing unit 204 provides the head-driving unit 208 with a selection code (SC) specifying the on and off states of the nozzle 118 at each discharging timing, based on the discharging data stored in the storage unit 202 and the ejection period (EP). The head-driving unit 208 provides the head 114 with the ejection period (EP) needed for discharging the liquid material 111, based on the selection code (SC). As a result, the liquid material 111 is discharged in the form of a droplet through the corresponding nozzle 118 in the head 114.

The controlling unit 112 may be a computer including a central processing unit (CPU), read-only memory (ROM), and random-access memory (RAM). In this case, the functions of the controlling unit 112 are accomplished by a computer program. The controlling unit 112 may be accomplished with a dedicated circuit (hardware).

The configuration and functions of the head-driving unit 208 in the controlling unit 112 will be described.

As shown in FIG. 7A, the head-driving unit 208 includes a driving-signal generator 203 and a plurality of analog switches (AS). AS shown in FIG. 7B, the driving-signal generator 203 generates a driving signal (DS). The electric potential of the driving signal (DS) is changed with time, based on the reference potential L. The driving signal (DS) includes a plurality of ejection waveforms P at respective ejection periods (EP), each of the ejection waveforms P being repeatedly generated every ejection period (EP). The ejection waveforms P corresponds to a waveform of a driving voltage applied to a pair of electrodes of the corresponding vibrator 124 in order to discharge a droplet through the nozzle 118.

The driving signal (DS) is supplied to an input terminal of each analog switch (AS). Each of the analog switches (AS) is disposed corresponding to each discharging portion 127. That is, the number of analog switches (AS) is identical to the number of discharging portions 127 (the number of nozzle 118).

The processing unit 204 provides each analog switch (AS) with the selection code (SC) indicating the on and off states of the nozzle 118. The selection code (SC) can be independently set in a high or low level for each analog switch (AS). The analog switches (AS) supply the electrode 124A of the vibrator 124 with an ejection signal (ES) according to the driving signal (DS) and the selection code (SC). When the selection code (SC) is a high level, the analog switch (AS) outputs the driving signal (DS) as the ejection signal (ES) to the electrode 124A. When the selection code (SC) is a low level, the potential of the ejection signal (ES) outputted from the analog switch (AS) is reference potential L. Providing the electrode 124A of the vibrator 124 with a driving signal (DS) results in the discharge of the liquid material 111 through the nozzle 118 corresponding to the vibrator 124. The potential of the electrode 124B of the vibrator 124 is the reference potential L.

As shown in FIG. 7B, a high-level period and a low-level period in each of the two selection codes (SC) are set so that the ejection waveforms P is generated at twice the ejection period (EP) in each of the two ejection signals (ES). As a result, the liquid material 111 is discharged through the corresponding two nozzles 118 at a period of 2EP. Each of the vibrators 124 corresponding to the two nozzles 118 is provided with the common driving signal (DS) from the common driving-signal generator 203. Therefore, the liquid material 111 is discharged at substantially the same timing through the two nozzles 118.

The liquid material 111 is applied by scanning with the droplet-discharging apparatus 100 including the configuration described above according to the discharging data supplying to controlling unit 112.

(Method for Applying Material)

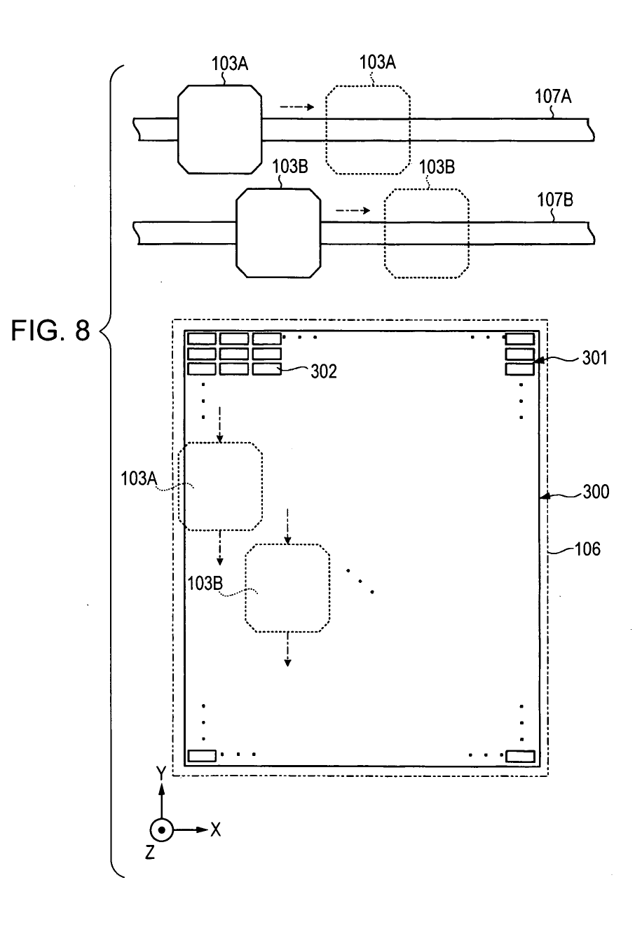

With reference to FIG. 8, an embodiment of a method for applying a material with the droplet-discharging apparatus 100 will be described below. FIG. 8 is a schematic view illustrating an embodiment of a method for applying a material with the droplet-discharging apparatus 100. A base 300 is retained on the platform 106. Predetermined portions 302 to be applied are arrayed in a matrix on the base 300, the predetermined portions 302 being separated with respective banks 301. The predetermined portions 302 are regions where, for example, pixels are provided. The planar image of the predetermined portions 302 has a nearly rectangular shape having a long side and a short side. The platform 106 retains the base 300 so that the long side of each predetermined portion 302 is parallel to the x-axis and the short side of each predetermined portion 302 is parallel to the y-axis.

In FIG. 8, the position of the first carriage 103A is set at the position of the base 300 on the platform 106. As described above, the second carriage 103B is moved along the x-axis so that the nozzle pitch between the head group 114G on the first carriage 103A and the head group 114G on the second carriage 103B is a predetermined nozzle pitch (nozzle pitch GXP along the x-axis in FIG. 5: 17.5 μm). As a result, the relative position of the first and second carriages 103A and 103B is adjusted.

The droplets of the liquid material 111 are discharged onto the predetermined portions 302 on the base 300 from the head groups 114G on the first and second carriages 103A and 103B along the y-axis while the first and second carriages 103A and 103B are relatively moving for the platform 106 along the y-axis.

The first and second carriages 103A and 103B are synchronously moved along the x-axis by a width in which the apparatus can discharge a material in a single operation (effective scan width) while the relative position of the first and second carriages 103A and 103B is maintained. The droplets of the liquid material 111 are discharged onto the predetermined portions 302 on the base 300 from the head groups 114G on the first and second carriages 103A and 103B while the first and second carriages 103A and 103B are relatively moved along the y-axis for the platform 106. The same operation is repeated until all of the predetermined portions 302 on the base 300 are applied.

(Modification of Relative Position)

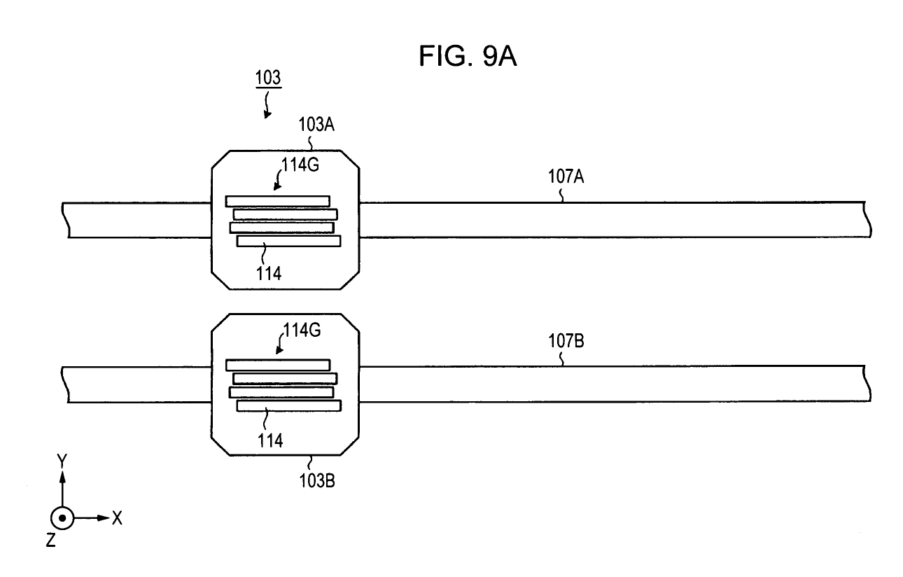

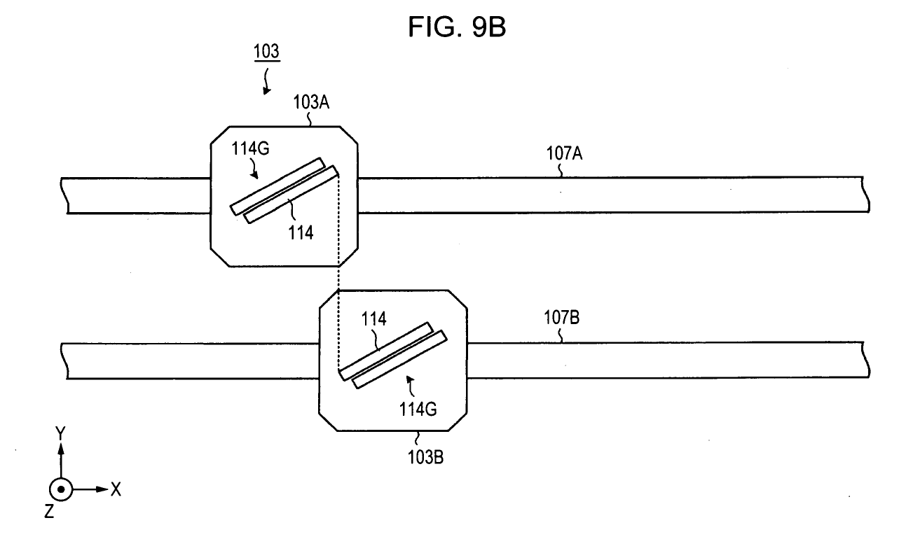

FIG. 9A is a schematic view showing a relative position of the first and second carriages 103A and 103B according to a modified embodiment. In the above-described embodiment, the head group 114G on the first carriage 103A and the head group 114G on the second carriage 103B are arranged along the x-axis in order to double the scan width, and then the relative position of the first and second carriages 103A and 103B is adjusted. However, the invention is not limited to this. For example, as shown in FIG. 9A, the head group 114G on the first carriage 103A and the head group 114G on the second carriage 103B are arranged along the y-axis in order to densify the linear density of the nozzles, and then the relative position of the first and second carriages 103A and 103B may be adjusted. In this way, there are two types of arrangements for the first and second carriages 103A and 103B: an arrangement along the x-axis to double the scan width; and an arrangement along the y-axis to densify the linear density of the nozzles.

(Modification of Head Arrangement)

FIG. 9B is a schematic view showing an arrangement of heads 114 according to a modified embodiment. In the above-described embodiment, the heads 114 are provided on the first and second carriages 103A and 103B so that the nozzle lines are arranged parallel to the x-axis. On the other hand, in this modification as shown in FIG. 9B, the heads 114 are provided on the first and second carriages 103A and 103B so that the nozzle lines of the heads 114 are arranged at an angle to the x-axis. Each of the head groups 114G includes the two heads 114. By arranging the nozzle lines at an angle to the x-axis, high-density application can be achieved with a small number of heads.

As described above, the droplet-discharging apparatus 100 according to this embodiment includes the first carriage 103A and the second carriage 103B, each including the head group 114G having at least one head 114 with a nozzle line and each being moved in the sub-scanning direction (along the x-axis) on the feed shafts 107A and 107B; and the first position-controlling unit 104 for adjusting relative position of the adjacent head groups 114G arranged in the main scanning direction (along the y-axis) to adjust the nozzle pitch by independently driving the first and second carriages 103A and 103B, wherein a droplet is discharged onto the predetermined portions 302 on the base 300 from the head groups 114G while the first and second carriages 103A and 103B are relatively moved for the platform 106 in the main scanning direction (along the y-axis). In the droplet-discharging apparatus 100, the nozzle pitch between the head groups 114G can be adjusted by moving the first and second carriages 103A and 103B. In this way, the nozzle pitch can be easily adjusted, and thus the application can be performed with high accuracy.

(Modification 1 of Carriage)

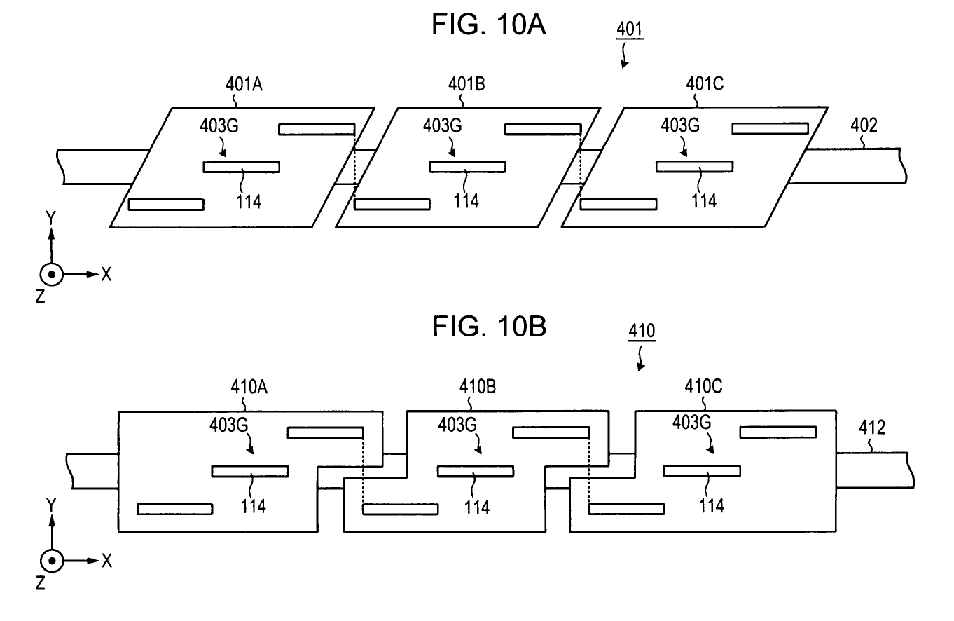

FIGS. 10A and 10B each are a schematic view showing carriages according to a modified embodiment 1. In the above-described embodiment, the first and second carriages 103A and 103B are disposed on different feed shafts from each other. On the other hand, in Modification 1, a plurality of carriages are disposed on the same feed shaft. As shown in FIG. 10B, a carriage group 401 includes a first carriage 401A, a second carriage 401B, and a third carriage 401C. The first, second, and third carriages 401A, 401B, and 401C are disposed on the same feed shaft 402. The first, second, and third carriages 401A, 401B, and 401C have the same configuration. Their planar images each have a parallelogram shape having two sides parallel to the x-axis and two parallel sides at an angle to the y-axis.

The first, second, and third carriages 401A, 401B, and 401C each include a head group 403G. Each of the head groups 403G includes three heads 114. Each of the heads 114 has the same arrangement. The three heads constituting each head group 403G are arranged along the x-axis and at the top right, middle, and bottom left of each carriage so that the scan width is triple that of each head 114. Each of the heads 114 has the undersurface with a plurality of nozzles 118. The undersurfaces of the heads 114 fixed on the first, second, and third carriages 401A, 401B, and 401C faces the platform 106. Each of the heads 114 has a long side and a short side parallel to the x-axis and y-axis, respectively.

When the adjacent carriages along the x-axis come close to each other, the nozzle line in the top-right head 114 in one head group 403G and the nozzle line in the bottom-left head 114 in another head group 403G are at least partially overlapping each other along the y-axis. In FIG. 10A, the nozzle line in the top-right head 114 in the head group 403G on the first carriage 401A and the nozzle line in the bottom-left head 114 in the head group 403G on the second carriage 401B are at least partially overlapping each other along the y-axis. Furthermore, the nozzle line in the top-right head 114 in the head group 403G on the second carriage 401B and the nozzle line in the bottom-left head 114 in the head group 403G on the third carriage 401C are at least partially overlapping each other along the y-axis.

The first position-controlling unit 104 relatively moves the first and second carriages 401A and 401B so that the nozzle pitch between the head group 403G on the first carriage 401A and the head group 403G on the second carriage 401B has a predetermined distance. In this case, θ is also adjusted. The relative position can be adjusted by the same process as that described above.

Then, the first position-controlling unit 104 relatively moves the third carriage 401C so that the nozzle pitch between the head group 403G on the second carriage 401B and the head group 403G on the third carriage 401C has a predetermined distance. In this case, θ is also adjusted. After the adjustment of the relative positions, the first position-controlling unit 104 synchronously moves the first, second, and third carriages 401A, 401B, and 401C along the x-axis while the relative positions are maintained. In this way, by adjusting the relative positions between the carriages, a scan width is triple that of one head group 114G and a nozzle pitch can be adjusted with high accuracy; thus, the application can be performed with high accuracy.

The droplet-discharging apparatus 100 according to this Modification 1 includes the first, second, and third carriages 401A, 401B, and 401C, each including the head group 403G having at least one head 114 with a nozzle line and each being moved in the sub-scanning direction (along the x-axis) on the same feed shaft 402; and the first position-controlling unit 104 for adjusting relative position of the adjacent head groups 403G arranged in the sub-scanning direction (along the x-axis) to adjust the nozzle pitch by independently driving the first, second, and third carriages 401A, 401B, and 401C, wherein a droplet is discharged onto the predetermined portions 302 on the base 300 from the head group 403G while the first, second, and third carriages 401A, 401B, and 401C are relatively moved for the platform 106 in the main scanning direction (along the y-axis). In the droplet-discharging apparatus 100, the nozzle pitch between the head groups 403G can be adjusted by moving the first, second, and third carriages 401A, 401B, and 401C. In this way, the nozzle pitch can be easily adjusted, and thus the application can be performed with high accuracy.

As shown in FIG. 10A, the carriages each have a parallelogram shape such that the nozzle line in the top-right head 114 in one head group 403G and the nozzle line in the bottom-left head 114 in another head group 403G are at least partially overlapping each other along the y-axis when the adjacent carriages along the x-axis come close to each other. However, the shape of the carriage is not limited to this. For example, as shown in FIG. 10B, the nozzle lines in the heads 114 on adjacent carriages along the x-axis may be at least partially overlapping along the y-axis using a first, second, and third carriages 410A, 410B, and 410C disposed on the feed shaft 412, the first, second, and third carriages 410A, 410B, and 410C each having a convex portion.

In Modification 1, the nozzle lines in the heads 114 may be arranged at an angle to the x-axis.

(Modification 2 of Carriage)

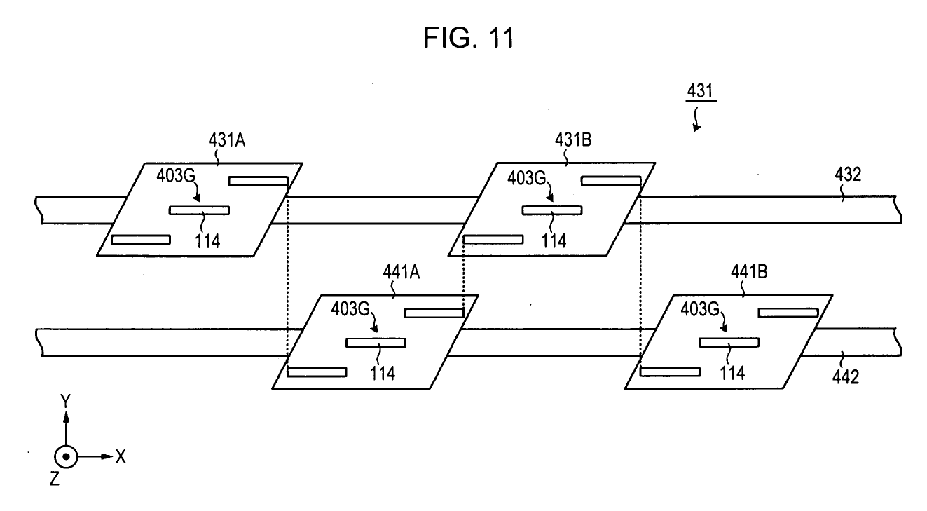

FIG. 11 is a schematic view showing carriages according to Modification 1. In Modification 2, two feed shafts each include a plurality of carriages. A first feed shaft 432 and a second feed shaft 442 are disposed in parallel and on the same xy-plane. A carriage group 431 includes first and second carriages 431A and 431B on the first feed shaft 432; and third and fourth carriages 441A and 441B on the second feed shaft 442.

The case in which application is performed at a scan width being four times that of one head group 403G will be described. The first position-controlling unit 104 relatively moves the first and third carriages 431A and 441A so that the nozzle pitch between the head group 403G on the first carriage 431A and the head group 403G on the third carriage 441A has a predetermined distance.

Then, the first position-controlling unit 104 relatively moves the second carriage 431B so that the nozzle pitch between the head group 403G on the third carriage 441A and the head group 403G on the second carriage 431B has a predetermined distance. In this case, θ is also adjusted.

Next, the first position-controlling unit 104 relatively moves the fourth carriage 441B so that the nozzle pitch between the head group 403G on the second carriage 431B and the head group 403G on the fourth carriage 441B has a predetermined distance. After the adjustment of the relative positions, the first position-controlling unit 104 synchronously moves the first, second, third, and fourth carriages 431A, 431B, 441A, and 441B along the x-axis while the relative positions are maintained. In this way, by adjusting the relative positions between the carriages, a scan width is four times that of one head group 114G and a nozzle pitch can be adjusted with high accuracy; thus, the application can be performed with high accuracy.

The case in which the scan width is increased has been described above. The relative position may also be adjusted so that the linear density of the nozzles is increased. For example, the first carriage 431A and the third carriage 441A are overlapped along the y-axis, and the second carriage 431B and the fourth carriage 441B also are overlapped along the y-axis.

The droplet-discharging apparatus 100 according to this Modification 2 includes the first, second, third, and fourth carriages 431A, 431B, 441A, and 441B, each including the head group 403G having at least one head 114 with a nozzle line and each being moved in the sub-scanning direction (along the x-axis) on the two feed shafts 432 and 442 arranged in parallel; and the first position-controlling unit 104 for adjusting relative position of the adjacent head groups 403G arranged in the main scanning direction (along the y-axis) to adjust the nozzle pitch by independently driving the first, second, third, and fourth carriages 431A, 431B, 441A, and 441B, wherein a droplet is discharged onto the predetermined portions 302 on the base 300 from the head group 403G while the first, second, third, and fourth carriages 431A, 431B, 441A, and 441B are relatively moved for the platform 106 in the sub-scanning direction (along the x-axis). In the droplet-discharging apparatus 100, the nozzle pitch can be adjusted between the head groups 403G by moving the first, second, third, and fourth carriages 431A, 431B, 441A, and 441B for the platform 106 in the sub-scanning direction (along the x-axis). In this way, the nozzle pitch can be easily adjusted, and thus the application can be performed with high accuracy.

In Modification 2, the nozzle lines in the heads 114 may be arranged at an angle to the x-axis.

(Production of Electro-Optical Device)

An electro-optical device (flat-panel display) produced by the droplet-discharging apparatus 100 according to the embodiment, for example, a color filter, a liquid crystal display device, an organic electroluminescent display, a plasma display panel (PDP), or an electron emission device (field emission display (FED) or surface-conduction electron-emitter display (SED)) will be described in structure. A method for producing the electro-optical device will also be described.

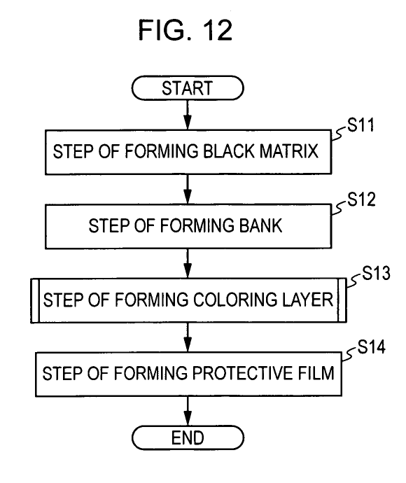

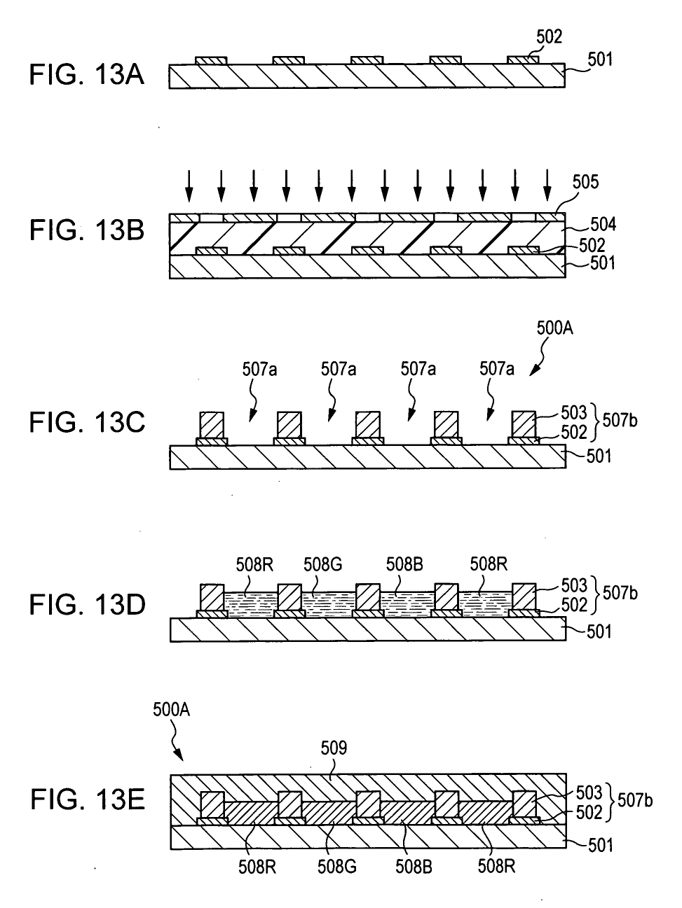

A method for producing a color filter used for a liquid crystal display device or an organic EL display will be described below. FIG. 12 is a flow chart illustrating steps of producing a color filter. FIGS. 13A to 13E each are a schematic cross-sectional view of a color filter 500 (filter base 500A) in each production step.

In a step of forming a black matrix (S11), as shown in FIG. 13A, black matrices 502 are formed on a substrate (W) 501. Each of the black matrices 502 is composed of chromium metal, a laminate of chromium metal and chromium oxide, or a resin. The black matrix 502 composed of a thin metal film can be formed by sputtering or vapor deposition. The black matrix 502 composed of a thin resin film can be formed by gravure printing, a photoresist process, or thermal transferring.

In a step of forming a bank (S12), banks 503 are formed on the black matrices 502. As shown in FIG. 13B, a transparent negative photo-sensitive resin is applied over the substrate 501 and the black matrices 502 to form a resist layer 504. A mask 505 having a matrix pattern is formed over the upper surface, and then an exposure is performed. As shown in FIG. 13C, the non-exposed portion of the resist layer 504 is patterned by etching to form the banks 503. When the black matrix is composed of a resin black, the black matrix also functions as a bank. Each of the banks 503 and the corresponding black matrix 502 under the bank 503 are combined to form a partition 507b. The partitions 507b separate pixel regions 507a. In a step of forming a coloring layer described below, the partitions 507b define regions for receiving functional droplets discharged from the head 114 in order to form coloring layers 508R, 508G, and 508B.

The filter base 500A is formed by the steps of forming a black matrix and bank. In this embodiment, the banks 503 are composed of a resin material in which the surface of a film composed of the resin material is lyophobic (hydrophobic). The surface of the substrate 501 composed of glass is lyophilic (hydrophilic). Thus, in a step of forming a coloring layer described below, the discharged droplets reach each of the pixel regions 507a surrounded by the banks 503 (partitions 507b) with higher precision.

In a step of forming a coloring layer (S13), as shown in FIG. 13E, functional droplets are discharged from the heads 114 onto each of the pixel regions 507a surrounded by the partitions 507b. In this case, the heads 114 are filled with three functional liquids for R, G, and B (materials for filter), and then the functional liquids are discharged. The arrangements for the R, G, and B may be, for example, a stripe arrangement, a mosaic arrangement, or a delta arrangement.

After drying (heating or the like), the functional liquids are fixed to three coloring layers 508R, 508G, and 508B. Next, in a step of forming a protective film (S14), as shown in FIG. 13E, a protective film 509 is formed over the substrate 501, the partition 507b, and the coloring layers 508R, 508G, and 508B. In other words, a liquid for forming the protective film is discharged over the coloring layers 508R, 508G, and 508B on the substrate 501 and then dried to form the protective film 509. Then, the substrate 501 is separated into an individual effective pixel region, thus resulting in the color filter 500.

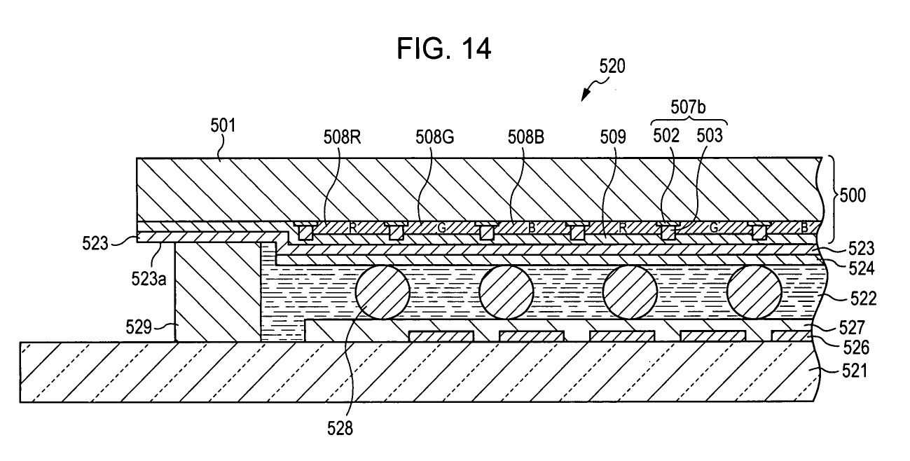

FIG. 14 is a sectional partially schematic view showing a passive matrix liquid crystal display device as an example of a liquid crystal display device with the color filter 500. Components such as an IC for driving the liquid crystal, a backlight, and a support are placed to this liquid crystal display device 520, thus resulting in a transmission liquid crystal display device as a final product. Since the color filter 500 is identical to that shown in FIG. 13, the corresponding portions have the same reference numerals. The description of the color filter is omitted.

The liquid crystal display device 520 includes the color filter 500, a counter substrate 521, and a liquid crystal layer 522 composed of a super twisted nematic (STN) liquid crystal composition therebetween. The color filter 500 is disposed at the top (viewer side). Polarizing plates are disposed on the counter substrate 521 and on the outer surface of the color filter 500, the outer surface being opposite the liquid crystal layer 522 (not shown). Furthermore, the backlight is disposed on the outer surface of the polarizing plate on the counter substrate 521 (not shown).

In FIG. 14, a plurality of first electrodes 523 are provided at predetermined intervals on the surface of the protective film 509 (surface near liquid crystal layer) on the color filter 500, each of the first electrodes 523 being flat and long in the horizontal direction in FIG. 14. A first alignment film 524 is provided on the surface of the first electrode 523, the surface being remote from the color filter 500. A plurality of second electrodes 526 are provided at predetermined intervals on the surface of the counter substrate 521, the surface being opposite the color filter 500 and the second electrodes 526 being flat and long in the direction perpendicular to the first electrodes 523. A second alignment film 527 is provided over the surfaces of the second electrodes 526, the surface being adjacent to the liquid crystal layer 522. The first electrodes 523 and the second electrodes 526 are each composed of a transparent conducting material such as indium tin oxide (ITO).

Spacers 528 in the liquid crystal layer 522 are provided for retaining the thickness of the liquid crystal layer 522 (cell gap) at a constant. A seal 529 is provided for preventing the leakage of the liquid crystal composition in the liquid crystal layer 522 to the exterior. An end of the first electrode 523 functions as a lead 523a and extends to the outside of the seal 529. Pixels are positioned at the intersections of the first electrodes 523 and the second electrodes 526. The coloring layers 508R, 508G, and 508B are provided at the positions of the pixels.

In a usual production process, on the color filter 500, the first electrodes 523 are formed by patterning, and then the first alignment film 524 is applied, thus resulting in the component of the side of the color filter 500. Aside from this, on the counter substrate 521, the second electrodes 526 are formed by patterning, and then the second alignment film 527 is applied, thus resulting in the component of the side of the counter substrate 521. Next, the spacers 528 and seal 529 are formed on the component including the counter substrate 521. Then, the component including the counter substrate 521 and the component including the color filter 500 are bonded together. A liquid crystal constituting the liquid crystal layer 522 is charged through an inlet at the seal 529, and then the inlet is closed. Next, the polarizing plates and the backlight are stacked.

The droplet-discharging apparatus 100 according to this embodiment can apply, for example, a material (functional liquid) for forming the spacer constituting the cell gap and uniformly apply a liquid crystal (functional liquid) to a region surrounded by the seal 529 before the component including the counter substrate 521 and the component including the color filter 500 are bonded together. The seal 529 can also be formed by discharging with the head 114. Furthermore, the first and second alignment films 524 and 527 can be formed by discharging with the head 114.

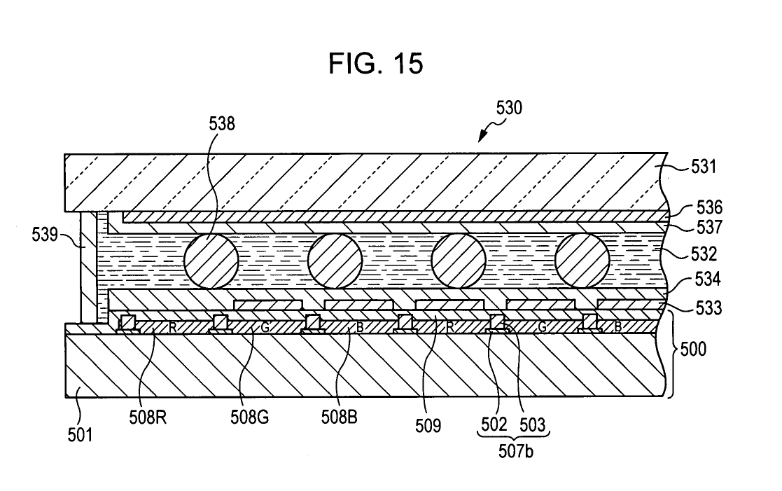

FIG. 15 is a sectional partially schematic view showing a second example of a liquid crystal display device with the color filter 500. The large difference between a liquid crystal display device 530 and the above-described liquid crystal display device 520 is that the color filter 500 is provided at the under side in FIG. 15 (opposite side of viewer). The liquid crystal display device 530 includes a liquid crystal layer 532 composed of a STN liquid crystal between the color filter 500 and a counter substrate 531. For example, the polarizing plates are provided on the outer surfaces of the counter substrate 531 and the color filter 500 (not shown).

A plurality of first electrodes 533 are provided at predetermined intervals on the surface of the protective film 509 (surface near liquid crystal layer 532) on the color filter 500, each of the first electrodes 533 being flat and long in the direction perpendicular to the plane of the paper on which FIG. 15 is drawn. A first alignment film 534 is provided on the surface of the first electrode 533, the surface being adjacent to the liquid crystal layer 532. A plurality of second electrodes 536 is provided at predetermined intervals on the surface of the counter substrate 521, the surface being opposite the color filter 500 and the second electrodes 536 being flat and extending in the direction perpendicular to the first electrodes 533. A second alignment film 537 is provided over the surfaces of the second electrodes 536, the surface being adjacent to the liquid crystal layer 532.

Spacers 538 in the liquid crystal layer 532 are provided for retaining the thickness of the liquid crystal layer 532 at a constant. A seal 539 is provided for preventing the leakage of the liquid crystal composition in the liquid crystal layer 532 to the exterior. Pixels are positioned at the intersections of the first electrodes 533 and the second electrodes 536 as in liquid crystal display device 520. The coloring layers 508R, 508G, and 508B are provided at the positions of the pixels.

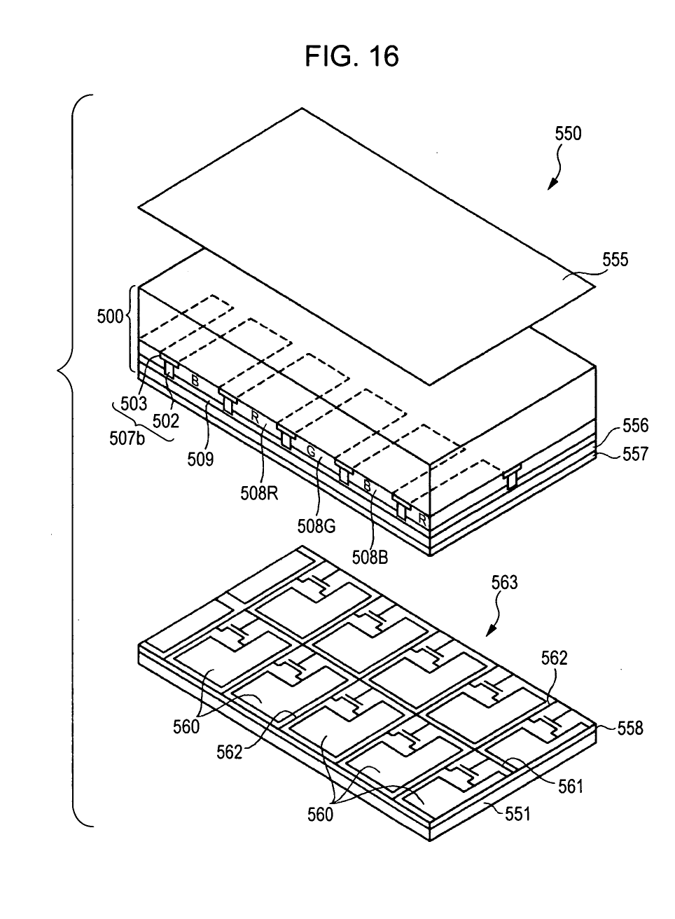

FIG. 16 shows a third example of a liquid crystal display device with the color filter 500 and is an exploded perspective view showing a transmission thin film transistor (TFT) liquid crystal display device. In this liquid crystal display device 550, the color filter 500 is provided at the top side in FIG. 16 (viewer side).

The liquid crystal display device 550 includes the color filter 500, a counter electrode 551 remote from the color filter 500, a liquid crystal layer therebetween (not shown), a polarizing plate 555 disposed at the top surface of the color filter 500 (viewer side), and a polarizing plate disposed at the undersurface of the counter electrode 551 (not shown). An electrode 556 for driving the liquid crystal is provided on the surface of the protective film 509 (the surface close to counter electrode 551) in the color filter 500. The electrode 556 is composed of a transparent conducting material such as ITO and covers the entire region having pixel electrodes 560 described below. An alignment film 557 is provided on the surface of the electrode 556, the surface being adjacent to the pixel electrodes 560.

An insulating layer 558 is provided on the surface of the counter electrode 551, the surface being adjacent to the color filter 500. Scanning lines 561 and signal lines 562 are provided on the insulating layer 558, the scanning lines 561 and the signal lines 562 being perpendicular to each other. Each of the pixel electrodes 560 is provided surrounded by the scanning lines 561 and the signal lines 562. In an actual liquid crystal display device, an alignment film is provided on the pixel electrodes 560, but not shown in FIG. 16.

Thin film transistors (TFTs) 563, each including a source electrode, a drain electrode, a semiconductor, and a gate electrode, are each provided at a region surrounded by the notched portion of the pixel electrode 560, the scanning lines 561, and the signal lines 562. The on and off states of each TFT 563 are controlled by applying a signal to the scanning lines 561 and the signal lines 562, thus controlling the pixel electrodes 560.

In the above-described embodiments, the transmission liquid crystal display devices 520, 530, and 550 have been described a reflective liquid crystal display device or a transflective liquid crystal display device may be produced by further providing a reflector or a transflector.

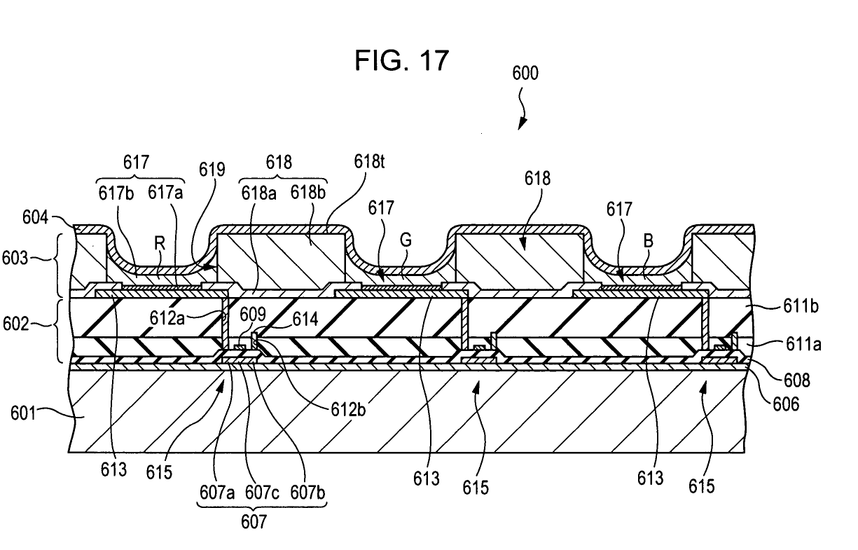

FIG. 17 is a partially cross-sectional view showing the display region of an organic electroluminescent display (hereinafter, referred to as “EL display 600”).

The EL display 600 includes a circuit element portion 602, a luminescent element portion 603, and a cathode 604 on a substrate (W) 601. In this EL display 600, light emitted from the luminescent element portion 603 toward the substrate 601 passes through the circuit element portion 602 and the substrate 601, and then emerges from the bottom of the substrate 601 toward a viewer. Light emitted from the luminescent element portion 603 toward the opposite side of the substrate 601 is reflected by the cathode 604 and passes through the circuit element portion 602 and the substrate 601, and then emerges from the bottom of the substrate 601 toward the viewer.

A substrate-protecting film 606 composed of silicon oxide between the circuit element portion 602 and the substrate 601. Semiconductor films 607 composed of polysilicon are provided on the surface of the substrate-protecting film 606, the surface close to luminescent element portion 603), the semiconductor film 607 each being in the form of an island. A heavily cation-doped source region 607a and a heavily cation-doped drain region 607b are formed at the respective sides of each semiconductor film 607 by ion implantation. The non-doped middle region of each semiconductor film 607 is defined as a channel region 607c.

The circuit element portion 602 includes the substrate-protecting film 606 and a transparent gate-insulating film 608 covering the semiconductor film 607. Gate electrodes 609 composed of, for example, Al, Mo, Ta, or W are each provided at a portion on the gate-insulating film 608, the portion corresponding to the channel region 607c in the semiconductor film 607. A transparent first interlayer insulating film 611a and second interlayer insulating film 11b are provided on the gate electrode 609 and the gate-insulating film 608. Contact holes 612a passing through both of the first and second interlayer insulating films 611a and 611b are provided, the contact holes 612a being connected to the respective source regions 607a. Contact holes 612b passing through the first interlayer insulating film 611a are provided, the contact holes 612b being connected to the respective drain regions 607b.

Transparent pixel electrodes 613 composed of, for example, ITO are provided on the second interlayer insulating film 611b, the pixel electrodes 613 having a predetermined shape. Each of the pixel electrodes 613 is connected to the corresponding source region 607a through the contact holes 612a. Power lines 614 are provided on the respective first interlayer insulating films 611a. Each of the power lines 614 is connected to the drain region 607b through the contact holes 612b.

In this way, the circuit element portion 602 includes thin film transistors 615 each connected to the corresponding pixel electrode 613.

The luminescent element portion 603 includes functional layers 617 stacked on the respective pixel electrodes 613 and bank portions 618 provided between the pixel electrodes 613 (between the functional layers 617), the bank portions 618 partitioning the functional layers 617. Luminescent elements are each composed of the corresponding pixel electrode 613, functional layer 617, and a cathode 604 provided on the pixel electrodes 613. The pixel electrodes 613 each have a nearly rectangular shape when viewed in plan. Each of the bank portions 618 is provided between the pixel electrodes 613.

The bank portions 618 are each composed of an inorganic bank layer 618a (first bank layer) and an organic bank layer 618b (second bank layer) on the inorganic bank layer 618a. The inorganic bank layer 618a is composed of an inorganic material such as SiO, SiO₂, or TiO₂. The organic bank layer 618b is composed of a resist such as an acrylic resin or a polyimide resin, the resist having excellent heat resistance and solvent resistance, the organic bank layer 618b having a trapezoidal cross-section. Each of the bank portions 618 partially covers the peripheral portion of the corresponding pixel electrode 613. Apertures 619 are provided on the respective pixel electrodes 613 between the bank portions 618, each of the apertures 619 diverging upward.

The functional layers 617 each include a hole injecting and/or transporting sublayer 617a stacked on the corresponding pixel electrode 613 and a luminescent sublayer 617b on the hole injecting and/or transporting sublayer 617a in the corresponding aperture 619. Any other functional sublayer may be further provided adjacent to the luminescent sublayer 617b. For example, an electron-transporting sublayer may be provided.

Each of the hole injecting and/or transporting sublayers 617a transports holes from the corresponding pixel electrode 613 and injects the holes into the corresponding luminescent sublayer 617b. The hole injecting and/or transporting sublayers 617a are formed by discharging a first composition (functional liquid). An example of the composition used for the hole injecting and/or transporting sublayer 617a includes a mixture containing a polythiophene derivative such as polyethylenedioxythiophene and polystyrene sulfonic acid, etc.

The luminescent sublayers 617b each emit red light (R), green light (G), or blue light (B). The luminescent sublayers 617b are formed by discharging a second composition (functional liquid). A nonpolar solvent in which the hole injecting and/or transporting sublayer 617a is not dissolved is suitably used as the solvent for the second composition. Examples of the solvent include cyclohexylbenzene, dihydrobenzofuran, trimethylbenzene, and tetramethylbenzene. By using such a nonpolar solvent as the solvent for the second composition used for the luminescent sublayer 617b, the luminescent sublayer 617b can be formed without redissolution of the hole injecting and/or transporting sublayer 617a.

Recombination of electrons and holes injected into the luminescent sublayer 617b from the hole injecting and/or transporting sublayer 617a results in the emission of light.

The cathode 604 covers the entire surface of the luminescent element portion 603 and is paired with each of the pixel electrodes 613 to feed current through the corresponding functional layer 617. A sealing component (not shown) is provided on the cathode 604.

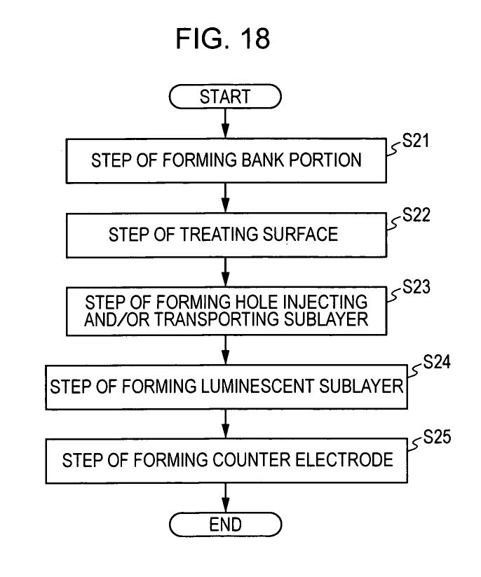

Steps of producing the EL display 600 will be described below with reference to FIGS. 18 to 26.

As shown in FIG. 18, the EL display 600 is produced through the following steps: a step of forming a bank portion (S21); a step of treating a surface (S22); a step of forming a step of forming a hole injecting and/or transporting sublayer (S23); a step of forming a luminescent sublayer; and a step of forming a counter electrode (S25). The production steps are not limited to the steps exemplified. If necessary, the production steps may be omitted and further include any other step.

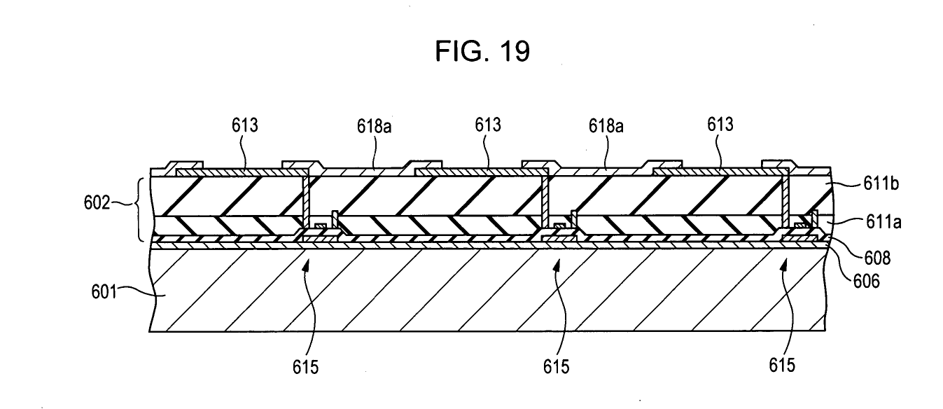

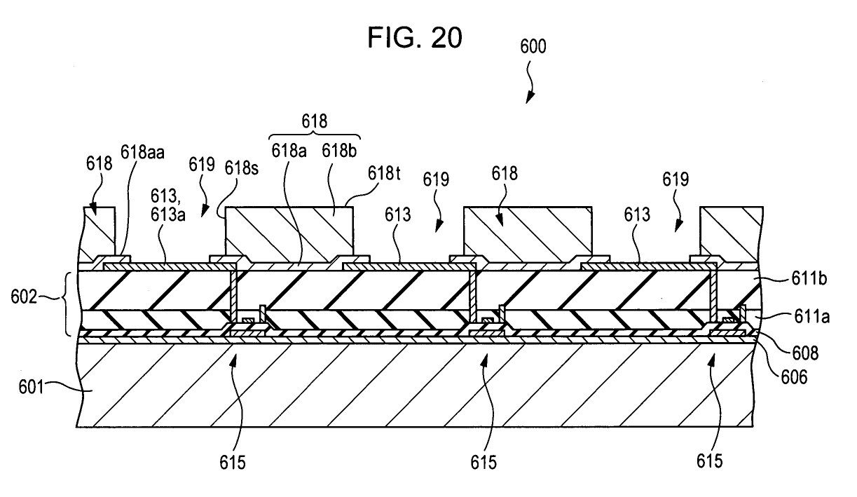

As shown in FIG. 19, in the step of forming bank portion (S21), the inorganic bank layers 618a are formed on the second interlayer insulating film 611b. An inorganic film is formed on a predetermined position, and then the inorganic film is subjected to patterning by, for example, photolithography to form the inorganic bank layers 618a. Each of the inorganic bank layers 618a is formed so as to partially cover the periphery of the corresponding pixel electrode 613. As shown in FIG. 20, after forming the inorganic bank layer 618a, the organic bank layers 618b are formed on the respective inorganic bank layers 618a. The organic bank layers 618b are formed by, for example, photolithography in the same way as for the inorganic bank layers 618a. In this way, the bank portions 618 are formed. The apertures 619 are inevitably formed between the bank portions 618, each of the bank portions 618 diverging upward. The apertures 619 define pixel regions.

In the step of treating a surface (S22), lyophilic treatment and lyophobic treatment are performed. Regions to be subjected to lyophilic treatment are the first stacked portions 618aa of each inorganic bank layer 618a and the electrode surface 613a of each pixel electrode 613. These regions are subjected to plasma treatment with a treating gas, for example, oxygen, thus resulting in lyophilic surfaces. The plasma treatment also serves as cleaning of the pixel electrodes 613 composed of ITO. On the other hand, Regions to be subjected to lyophilic treatment are the side faces 618s of each organic bank layer 618b and the top surface 618t of each organic bank layer 618b. These regions are subjected to plasma treatment with a treating gas, for example, tetrafluoromethane, thus resulting in lyophobic surface. By performing this surface-treating step, the droplets composed of the functional liquid can surely reach the pixel regions in forming the functional layers 617 by discharging the functional liquid from the heads 114. Furthermore, overflow of the functional liquid in the pixel regions from the apertures 619 can be prevented.

A base 600A for the EL display is produced through the above-described steps. The base 600A for the EL display is placed on the droplet-discharging apparatus 100 shown in FIG. 1, and then the following steps are performed: a step of forming hole injecting and/or transporting sublayer (S23); and a step of forming luminescent sublayer (S24).

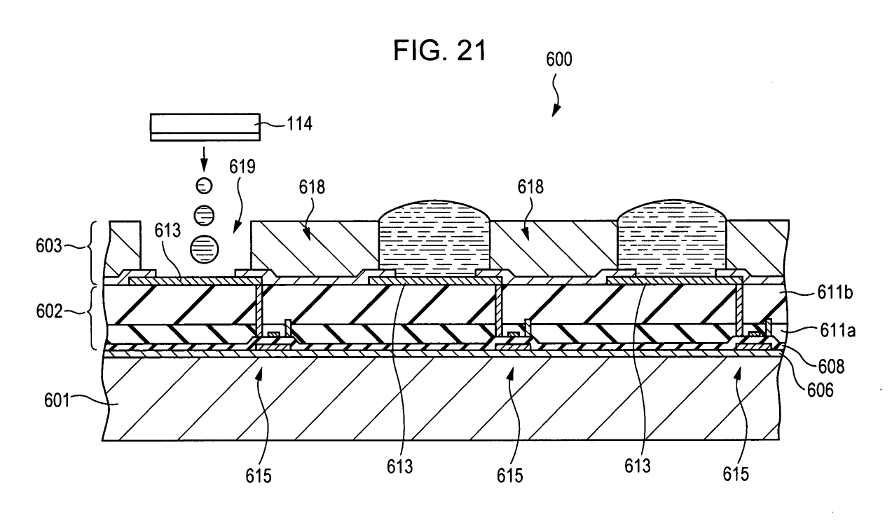

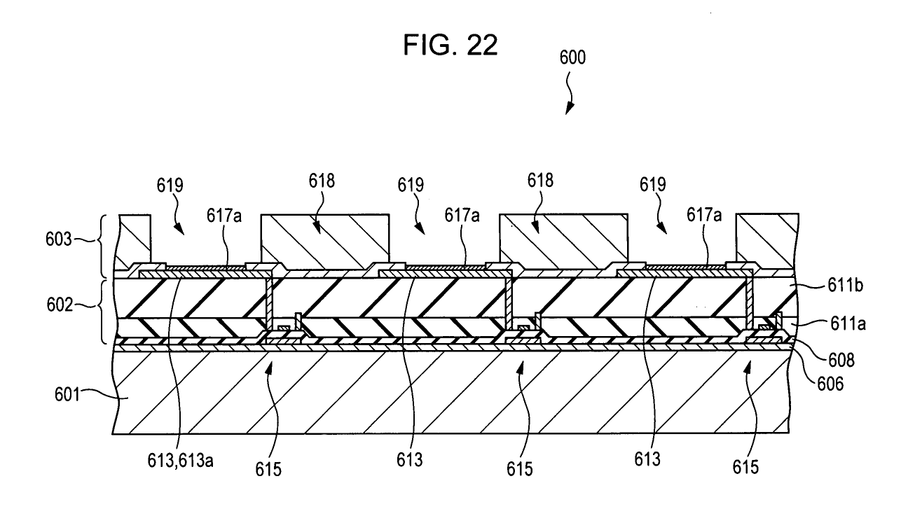

As shown in FIG. 21, in the step of forming hole injecting and/or transporting sublayer (S23), the first composition containing a material for hole injecting and/or transporting sublayer is discharged from the heads 114 onto the apertures 619. As shown in FIG. 22, a nonpolar solvent containing the first composition is evaporated by drying and heating, thus resulting in the hole injecting and/or transporting sublayers 617a on the respective pixel electrodes 613 (on the respective electrode surfaces 613a).

The step of forming a luminescent sublayer (S24) will be described below. In this step, as described above, in order to prevent redissolution of the hole injecting and/or transporting sublayer 617a, a nonpolar solvent in which the hole injecting and/or transporting sublayer 617a is not dissolved is used as a solvent for the second composition used for forming the luminescent sublayer. However, the hole injecting and/or transporting sublayer 617a has a low affinity for such a nonpolar solvent. Therefore, when the second composition containing a nonpolar solvent is discharged onto the hole injecting and/or transporting sublayer 617a, each of the hole injecting and/or transporting sublayer 617a cannot be brought into close contact with the corresponding functional layer 617 or the luminescent sublayer 617b may be applied nonuniformly. In order to enhance the affinity of the surfaces of the hole injecting and/or transporting sublayers 617a for a nonpolar solvent and a material used for the luminescent sublayers, surface treatment (surface modification) is preferably performed before forming the luminescent sublayers. This surface treatment is performed as follows: a surface-modifying material, that is, a solvent identical or similar to a nonpolar solvent for the second composition used in forming the luminescent sublayers is applied onto the hole injecting and/or transporting sublayers 617a and then dried. As a result, the surface of each hole injecting and/or transporting sublayer 617a has a higher affinity for the nonpolar solvent. Thus, in the following step, the second composition containing the material for forming the luminescent sublayers is applied uniformly onto the hole injecting and/or transporting sublayers 617a.

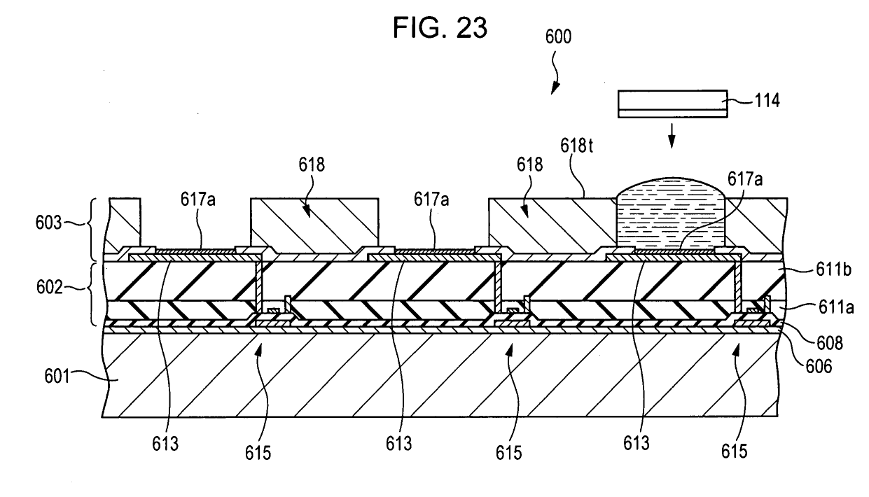

As shown in FIG. 23, a predetermined amount of functional droplets composed of the second composition containing a material for forming the luminescent sublayers are discharged into the pixel regions (apertures 619), the material corresponding to one color selected among the three colors (in FIG. 23, blue (B)). The discharged second composition into the pixel regions spreads over each hole injecting and/or transporting sublayers 617a, and then the apertures 619 are filled with the second composition. Even in the event that the second composition is discharged onto the top surfaces 618t of the bank portions 618 out of the target pixel regions, the second composition easily moves from the top surfaces 618t into the apertures 619 because the top surfaces 618t are subjected to the lyophobic treatment as described above.

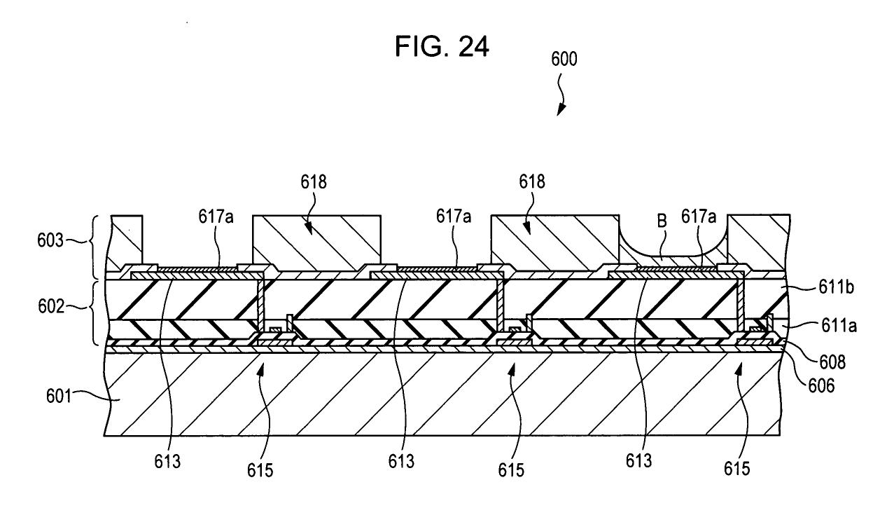

As shown in FIG. 24, the resulting second composition is dried to evaporate the nonpolar solvent in the second composition, thus resulting in the luminescent sublayers 617b on the hole injecting and/or transporting sublayers 617a. In this FIG. 24, the luminescent sublayer 617b emitting blue light (B) is provided.

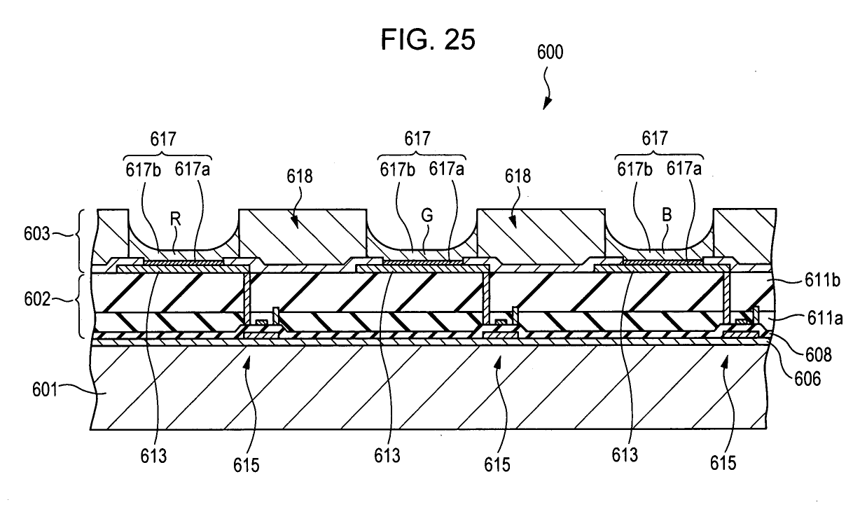

As shown in FIG. 25, the same steps as that of forming the luminescent sublayers 617b emitting blue light (B) as described above are performed so that the luminescent sublayers 617b corresponding to other colors (red (R) and green (G)) are formed. The order in which the three types of luminescent sublayers 617b are formed is not limited to that of the above-described embodiment. The luminescent sublayers 617b may be formed in any order. For example, the order can be determined depending on a material for forming the luminescent sublayers. In addition, the arrangements for the R, G, and B may be, for example, a stripe arrangement, a mosaic arrangement, or a delta arrangement.

As described above, the functional layers 617, that is, hole injecting and/or transporting sublayers 617a and luminescent sublayers 617b are formed on the respective pixel electrodes 613.

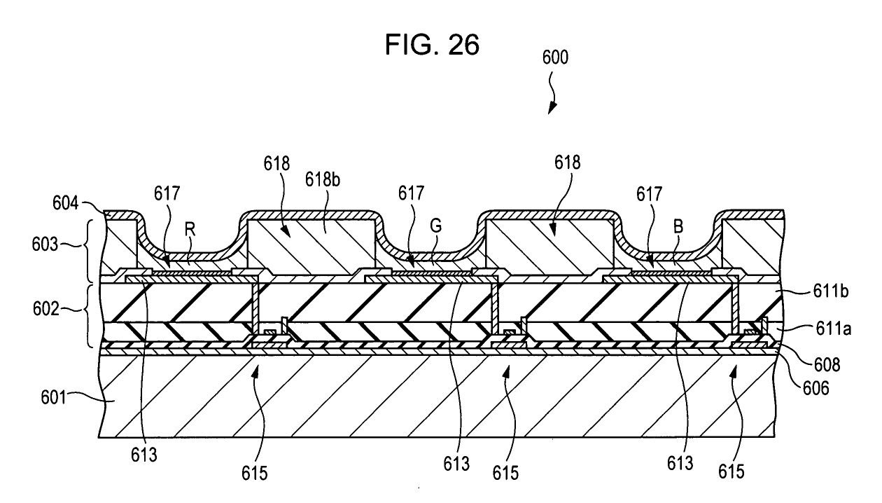

As shown in FIG. 26, in the step of forming a counter electrode (S25), the cathode 604 (counter electrode) is formed over the luminescent sublayers 617b and the organic bank layers 618b by, for example, vapor deposition, sputtering, chemical vapor deposition (CVD). In this embodiment, the cathode 604 is composed of, for example, a laminate of a calcium layer and an aluminum layer. An Al film or Ag film functioning as an electrode; or a protective film, such as a SiO₂ film or a SiN film, preventing oxidation of the electrode is appropriately formed on the cathode 604.

After the cathode 604 is thus formed, any other treatment, for example, sealing treatment for sealing the top of the cathode 604 with a sealant and/or wiring treatment, thus resulting in the EL display 600.

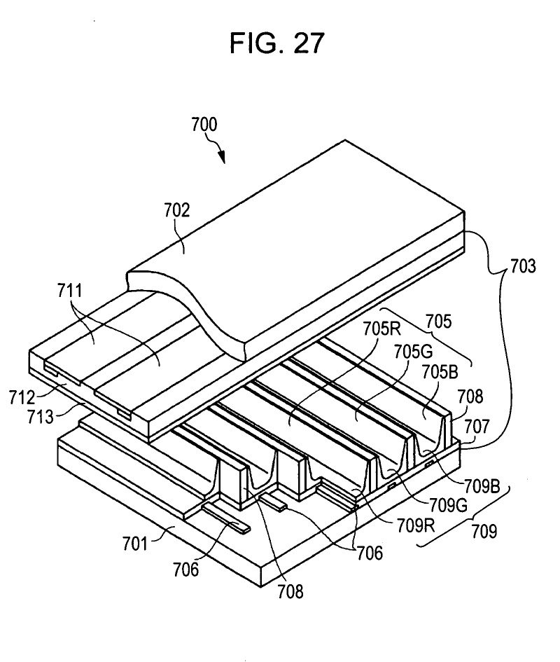

FIG. 27 is an exploded partially perspective view showing a plasma display panel (PDP) (hereinafter, referred to as “PDP 700”). In this FIG. 27, part of the cross-section of the PDP 700 is illustrated. The PDP 700 includes a first substrate 701; a second substrate 702; and a discharge display portion 703 therebetween, the first substrate 701 being opposite the second substrate 702. The discharge display portion 703 includes a plurality of discharge chambers 705. Among the plurality of discharge chambers 705, a red-discharge chamber 705R for emitting red light, a green-discharge chamber 705G for emitting green light, and a blue-discharge chamber 705B for emitting blue light are combined to constitute a pixel.

Address electrodes 706 are provided on the first substrate 701 at predetermined intervals, the address electrodes 706 having a striped pattern. A dielectric layer 707 is provided over the address electrodes 706 and the top surface of the first substrate 701. Partition group 708 are provided on the dielectric layer 707 between the address electrodes 706, the partition group 708 being along the address electrodes 706. The partition group 708 includes first partitions provided along the address electrodes 706 as shown in FIG. 27; and second partitions provided perpendicular to the address electrodes 706 (not shown). Regions partitioned by the partition group 708 are the discharge chambers 705.

Fluorescent materials 709 are provided in the discharge chambers 705. Each of the fluorescent materials 709 generates fluorescence of red (R), green (G), or blue (B). A red-fluorescent material 709R is provided at the bottom of the red-discharge chamber 705R. A green fluorescent material 709G is provided at the bottom of the green-discharge chamber 705G. A blue-fluorescent material 709B is provided at the bottom of the blue-discharge chamber 705B.

In FIG. 27, a plurality of display electrodes 711 are provided on the undersurface of the second substrate 702 at predetermined intervals and perpendicular to the address electrodes 706, the display electrodes 711 having a striped pattern. A dielectric layer 712 is provided over these. A protective film 713 composed of, for example, MgO is provided on the dielectric layer 712. The first substrate 701 and the second substrate 702 are bonded together so that the address electrodes 706 are perpendicular to the display electrodes 711. The address electrodes 706 and the display electrodes 711 each are connected to an AC power supply (not shown). By applying power to the electrodes 706 and 711, the fluorescent materials 709 are excited and then generate fluorescence. As a result, color images can be displayed.

In this embodiment, the address electrodes 706, the display electrodes 711, and the fluorescent materials 709 are formed with the droplet-discharging apparatus 100 shown in FIG. 1. An exemplary step of forming the address electrodes 706 on the first substrate 701 will be described below. The first substrate 701 is placed on the platform 106. Functional droplets composed of a liquid material (functional liquid) containing a material for the electrodes are discharged onto regions for forming the address electrodes from the heads 114. The liquid material is a dispersion containing conductive fine particles, such as a metal, as a conductive material in a dispersion medium. Examples of the conductive fine particles include metal fine particles containing gold, silver, cupper, palladium, or nickel; and conductive polymer.

After discharging the liquid material onto all of the regions for forming the address electrodes, the discharged liquid material is dried to evaporate the dispersion medium, thus resulting in the address electrodes 706.

The step of forming the address electrodes 706 have been described above. The display electrodes 711 and fluorescent materials 709 can also be formed through the same steps.

For forming the display electrodes 711, in the same way as for the address electrodes 706, functional droplets composed of a liquid material (functional liquid) containing a material for the electrodes are discharged onto regions for forming the display electrodes.

For forming the fluorescent materials 709, droplets composed of a liquid material (functional liquid) containing a red-, green-, or blue-fluorescent material are discharged onto the corresponding discharge chambers.

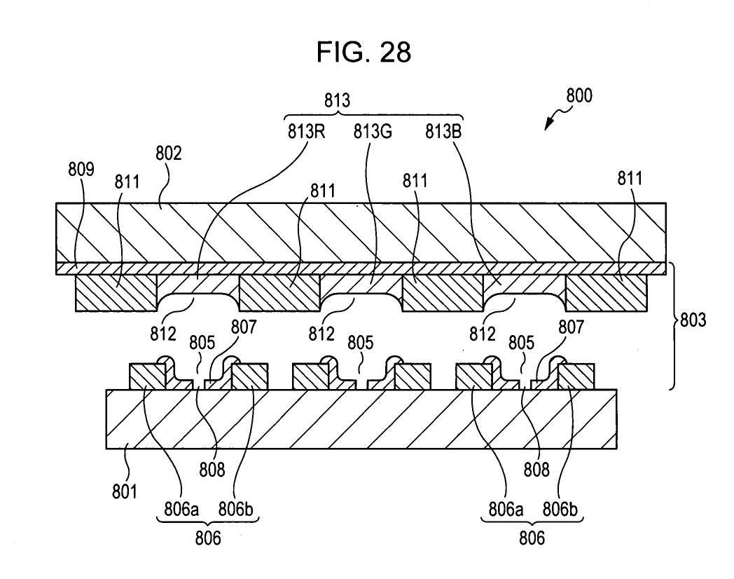

FIG. 28 is a partially cross-sectional view showing a field emission display (FED) (hereinafter, referred to as “FED 800”). The FED 800 includes a first substrate 801; a second substrate 802; and a field emission display portion 803 therebetween, the first substrate 801 being opposite the second substrate 802. The field emission display portion 803 includes a plurality of electron emission portion 805 arrayed in a matrix.

First element electrodes 806a and second element electrode 806b are perpendicular to each other on the top surface of the first substrate 801. Element films 807 each having a gap 808 are provided between the first element electrode 806a and the second element electrode 806b. That is, the plurality of electron emission portions 805 are composed of the first element electrodes 806a, the second element electrodes 806b, and the element films 807. The element films 807 are composed of, for example, palladium oxide (PdO). The gaps 808 are formed by forming after the element films 807 are formed.

An anode 809 is provided on the undersurface of the second substrate 802. Bank portions 811 are provided on the undersurface of the anode 809 in the form of a grid pattern. Fluorescent materials 813 are provided corresponding to the electron emission portions 805 and are provided in apertures 812 between the bank portions 811. The fluorescent materials 813 include a red-fluorescent material 813R emitting red light (R), a green-fluorescent material 813G emitting green light (G), and a blue-fluorescent 813B material emitting blue light (B). The red-fluorescent material 813R, the green-fluorescent material 813G, and the blue-fluorescent material 813B are provided at the respective apertures 812 in a predetermined pattern.

The first substrate 801 and the second substrate 802 are bonded together with a minute gap. In this FED 800, electrons emitted from the first element electrode 806a or the second element electrode 806b functioning as a cathode via the element film 807 (a gap 808) are incident on the fluorescent materials 813 on the anode 809. The fluorescent materials are excited and then generate fluorescence. In this way, color images can be displayed.

The first element electrodes 806a, second element electrode 806b, and anode 809 are also formed with the droplet-discharging apparatus 100. The fluorescent materials 813R, 813G, and 813B are also formed with the droplet-discharging apparatus 100.

An example of the other electro-optical device includes an electro-optical device having a step of forming metal wiring, lens, resist, light diffuser, and/or preparation. Various electro-optical devices can be efficiently produced with the droplet-discharging apparatus 100.

{Application for Electronic Apparatus}

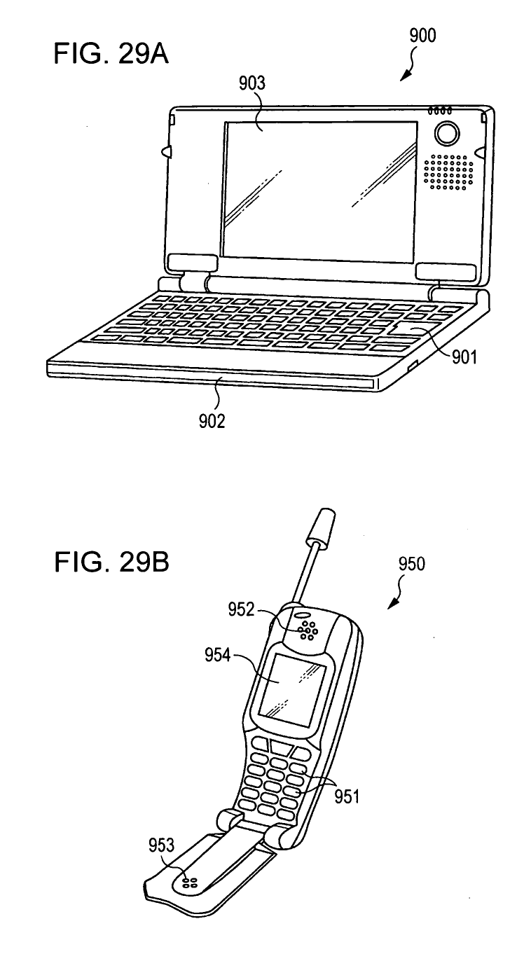

Examples of an electronic apparatus with the electro-optical device according to the invention will be described below with reference to FIGS. 29A and 29B. FIG. 29A is a perspective view showing a mobile personal computer 900 (that is, notebook computer) with an electro-optical device as a display according to the invention. The personal computer 900 includes a main body 902 having a keyboard 901, and a display 903 to which the electro-optical device according to the invention is applied. FIG. 29B is a perspective view showing a cellular telephone 950 with an electro-optical device as a display according to the invention. The cellular telephone 950 includes a plurality of operation buttons 951, ear piece 952, mouthpiece 953, and a display to which the electro-optical device 954 according to the invention is applied.

The electro-optical device according to the invention can be widely applied to electronic apparatuses such as personal digital assistants (PDA), work stations, digital still cameras, in-vehicle monitors, digital camcorders, liquid crystal display television sets, viewfinder or direct-vision monitor videotape recorders, car navigation systems, pagers, electronic organizers, electronic calculators, word processors, video phones, and point-of-sale terminals, other than the cellular telephone and the notebook computer.

A droplet-discharging apparatus according to the invention can be widely used for forming films in various industrial fields. An electro-optical device according to the invention can be widely used for organic electroluminescent displays, liquid crystal display devices, organic TFT display devices, plasma display devices, electrophoretic image display devices, electron emission display devices (field emission display devices and surface-conduction electron-emitter display, etc.), light-emitting diode (LED) display devices, electrochromic glass dimmers, and electronic papers.

1. A droplet-discharging apparatus for discharging a droplet onto a base through the nozzle of a head, the apparatus comprising:
a platform retaining the base;
a plurality of transportation units, each including a head group having at least one head with a nozzle line and each being moved in the sub-scanning direction on an axis or on a plurality of axes disposed parallel to each other; and
a position-controlling unit for adjusting relative position of the adjacent head groups arranged in the main scanning direction or in the sub-scanning direction to adjust the nozzle pitch by independently driving the plurality of transportation units, wherein the droplet is discharged onto predetermined portions on the base from the head group while the transportation units are relatively moved for the platform in the main scanning direction.

2. The droplet-discharging apparatus according to claim 1, wherein the position-controlling unit synchronously moves the plurality of transportation units in the sub-scanning direction while the adjusted relative position is maintained.

3. The droplet-discharging apparatus according to claim 1, wherein the position-controlling unit adjusts the relative position of the head groups on the adjacent transportation units arranged along the sub-scanning direction or the main scanning direction so that the nozzle pitch along the sub-scanning direction is uniformly spaced.

4. The droplet-discharging apparatus according to claim 1, wherein the position-controlling unit adjusts the relative position of the head groups on the adjacent transportation units arranged along the sub-scanning direction or the main scanning direction so that the linear density of the nozzles along the sub-scanning direction is increased.

5. The droplet-discharging apparatus according to claim 1, wherein the planar image of the predetermined portions has a nearly rectangular shape having a long side and a short side; and wherein the platform retains the base so that the long side of each predetermined portion is parallel to the sub-scanning direction and the short side of each predetermined portion is parallel to the main scanning direction.

6. The droplet-discharging apparatus according to claim 1, wherein the nozzle line in the head constituting the head group is disposed parrallel to the sub-scanning direction.

7. The droplet-discharging apparatus according to claim 1, wherein the nozzle line in the head constituting the head group is disposed at an angle to the sub-scanning direction.

8. An electro-optical device produced with the droplet-discharging apparatus according to claim 1.

9. A method for producing an electro-optical device with the droplet-discharging apparatus according to claim 1.

10. An electronic apparatus including the electro-optical device according to claim 8.
